(19) United States
(12) Patent Application Publication
(10) Pub. No.: US 2026/0138866 A1
(43) Pub. Date: May 21, 2026

(54) DESIGNS AND METHODS FOR MAUFACTURING OUT-OF-PLANE ROTATION STOPS FOR MEMS DEVICES

(71) Applicant: HUAWEI TECHNOLOGIES CO., LTD., Shenzhen (CN)

(72) Inventors: Mark MCNIE, Ipswich (GB); Pin YANG, Wuhan (CN)

(73) Assignee: HUAWEI TECHNOLOGIES CO., LTD., Shenzhen (CN)

(21) Appl. No.: 19/451,479

(22) Filed: Jan. 16, 2026

Related U.S. Application Data
(63) Continuation of application No. PCT/CN2023/108074, filed on Jul. 19, 2023.

(51) Int. Cl. B81B 3/00; B81B 5/00; B81C 1/00

(52) U.S. Cl. CPC B81B 3/0051; B81B 5/00; B81C 1/00198; B81B 2203/056; B81C 2201/0132

(57) ABSTRACT

A MEMS device comprising a stop for limiting the rotational motion of the rotor, the stop positioned such that on rotation of the rotor about its axis the first point of contact is between a surface of the stop facing away from the axis and a surface of the rotor facing towards the axis. A method of manufacturing a MEMS device comprising etching into a first layer to form the stator structure and at least one stop, where the stop comprises a trench formed by aspect ratio-dependent etching with walls bounding a landing site at the base of the trench, the stop is formed a distance away from an axis of rotation of a rotor such that on rotation of the rotor about its axis the base of the trench is contacted by the rotor before any other features of the device.

### CROSS-REFERENCE TO RELATED APPLICATIONS

This application is a continuation of International Application No. PCT/CN 2023/108074, filed on Jul. 19, 2023, the disclosure of which is hereby incorporated by reference in its entirety.

### TECHNICAL FIELD

This disclosure relates to out-of-plane rotation stop designs for use in MEMS devices and methods for manufacturing such designs.

### BACKGROUND

Micro-Electro-Mechanical Systems (MEMS) is the technology of microscopic devices which incorporate both electrical and moving parts. MEMS are typically made up of components between 1 and 1000 micrometres in size and MEMS devices generally range in size from 20 micrometres to 20 millimetres, although they can be arranged in arrays to form larger devices. Microsystems in general often consist of a central unit that processes data and several components that interact with the surroundings such as microsensors.

Because of the large surface area to volume ratio of MEMS, forces produced by ambient electromagnetism, such as electrostatic charges and magnetic moments, as well as fluid dynamics are more important design considerations than with larger scale mechanical devices. Examples of these very small machines are used for microswitches, micromirrors, accelerometers, gyroscopes, inertial measurement units, microphones, and in inkjet printers.

Micro-Electro-Mechanical systems (MEMS) contain moveable elements with motion which may be linear, rotational or a combination thereof. Stops have been used for many years to protect against excessive motion. The stops are also used to mitigate associated risks, including electrical damage like short circuits or electrical breakdown caused when elements at a different potential touch or come in close proximity, and mechanical damage, including over-stress that may result in fracture, plastic deformation, or fatigue. This excess motion may be caused by many factors, including shock, vibration, overdriving, overshoot (where in an underdamped regime), and electrostatic pull-in (or latching). Additionally, by controlling the contact area, stops can reduce the risk of stiction between elements that come into physical contact, which is when elements in contact and are unable to separate due to adhesion forces (including van der Waals, electrostatic or capillary forces). Most MEMS simply aim to avoid such contact in use, but some devices also use stops as a physical limit for digital actuation.

For the following discussion, an xy plane is defined as being parallel to the top surface of a substrate or base of the MEMS device. For example, the substrate may be a silicon wafer on which device chips are often manufactured. There is also defined a z direction, which is normal to the top surface of the substrate. Using these conventions, it is possible to broadly categorise two types of stop. The first type of stop is an in-plane (x, y) stop. An in-plane stop inhibits motion in the defined x and y directions parallel to the substrate, and rotational R_{z} motions around a z axis normal to the substrate. The second type of stop is an out-of-plane (z) stop. An out of plane stop inhibits motion in the z direction normal to the substrate, and rotational Rₓ, R_{y} motions around an axis parallel to the substrate, i.e., rotational motions with a vertical z component normal to the substrate. Stops are commonly found in micro-inertial sensors such as accelerometers and have also been used to inhibit both linear translational and rotational motion of micromirrors.

In-plane stops for translational motion have been widely used between a moveable structure and a fixed structure, but they are also possible between two moveable structures. Examples may be found in inertial sensors as described in US6272926B1 and US6360605B1. In-plane stops for rotational (R_{z}) motion, limit angle of rotation by defining an in-plane gap between structures at a chosen distance from the axis of rotation. Typically, in-plane stops comprise a protrusion or bump on one or both sides of a gap between structures such that the gap between structures is reduced locally. Such bumps also define the contact regions in the same plane.

Stops between moveable structures have the potential to store more energy to overcome adhesion forces and the potential to decrease the peak force on contact. In US6360605B1 compliant stops are used. US6923062B2 describes an array of cantilever stops comprising a series of cantilevers of different stiffness with bumps. US10527420B2 describes a dual gap compliant stop with a first gap between two surfaces that contact before two further surfaces with a larger second gap between them.

Out-of-plane stops (as described above) are designed to prevent a component of motion that is in a direction normal to the substrate, i.e., out of (an xy) plane of the substrate. As for in-plane translation stops, they are typically between a moveable structure and a fixed structure but they are also possible between two moveable structures or a combination thereof.

Unlike in-plane structures, out-of-plane stops are between structures extending different distances out of and in a direction normal to the substrate. This typically requires additional process steps to define the gap and typically requires a dedicated mask to define one or more of the stop layer patterns.

US6634232B1 describes stops on a moving portion of the device to limit z motion to a fixed part of the device. US20040025589A1 describes the use of a stop in z using a protrusion from a cap over the device's moveable structure. US7721604B2 describes a moveable structure rotating to stop when it contacts a surface in a different z plane at the same electrical potential. US8952466B2 describes an example compliant stop. US20170023606A1 describes a protrusion from the main rotating body which contacts a lower layer. US7119474B2 describes flexible rotation stops.

Most MEMS avoid unwanted contact whilst operating normally, however stops have been applied to MEMS micromirrors. US7139113B1 describes a digital mirror device (DMD) which uses stops as a physical limit of the mirror motion for digital actuation. US7535620B2 describes the use of mechanical stops to prevent undesirable displacements, such as shock. Specifically, one or more lateral mechanical stops on the axis of rotation to confine the flexible springs and prevent side snapping of the mirror support during operation, this can be classed as an in-plane stop.

US7863799B1 and US7986073B2 describe snapping tabs which are out-of-plane rotational stops. The tabs or protrusions extend from the rotor body at the furthest distance from the axis of rotation to contact to a lower level at the same electrical potential and halt rotation and include an in-plane stop at the tip of the protrusion to limit lateral motion which is fabricated in the same layer.

It is desirable to develop out-of-plane rotation stops that limit rotation of a MEMS device without adding process complexity (i.e., no additional masking steps or process steps) in a typical process flow for the manufacture of MEMS devices (e.g., micromirrors). The rotation limit prevents damage to the device from being over-stressed or short circuiting from being over-driven or from external factors, such as shock and vibration.

### SUMMARY

According to one aspect there is provided a micro-electro-mechanical device, the device comprising: a rotor having an axis of rotation along its length, and a stop for limiting the out-of-plane rotational motion of the rotor, the stop positioned such that on rotation of the rotor about the axis the first point of contact is between a surface of the stop facing away from the axis and a surface of the rotor facing towards the axis.

In an embodiment, the surface of the stop facing away from the axis may extend outwardly from a plane of a substrate of the device.

In an embodiment, the stop may be formed in one or more layers of the device that form a stator structure of the device. Thus the forming of the stop is part of the existing manufacturing steps.

In an embodiment, the rotor contacts the stop at a region of the stopper with the same potential as the rotor. Thus short circuits due to contact between the stop and the rotor are avoided.

In an embodiment, the rotor may define a throughway in which at least part of the stop is located. The throughway may therefore additionally inhibit some lateral motion.

In an embodiment, the device may comprise at least one spring biasing the rotor to an equilibrium state. The spring may therefore provide a non-powered restoring force to counteract stiction.

In an embodiment, the stop may be located such that when the rotor is in the equilibrium state the stop is spaced from the rotor in a direction normal to the substrate. The spacing allows for more efficient manufacturing and helps prevent short circuits.

In an embodiment, the stop may be located such that when the rotor is in an equilibrium state the stop overlaps the rotor in a direction normal to the substrate. This may improve manufacturing efficiency.

In an embodiment, the stop may be located such that when the rotor is in an equilibrium state the stop extends further from the substrate than the rotor. This may improve manufacturing efficiency.

In an embodiment, the micro-electro-mechanical device may comprise a plurality of stops, and the plurality of stops may be positioned symmetrically about a line along the axis of rotation of the rotor and may have the same dimensions as each other. Such a distribution may assist in balancing the mass moment around the axis of rotation.

In an embodiment, the micro-electro-mechanical device may comprise a plurality of stops, and the plurality of stops may be positioned asymmetrically about a line along the axis of rotation of the rotor and at least one stop of the plurality of stops may have different dimensions. This may allow for different degrees of rotation of the rotor in different directions about the axis of rotation and may also allow for the same angle of rotation of the rotor in different directions about the axis of rotation but with different sized gaps between the stop and rotor.

In an embodiment, the micro-electro-mechanical device may comprise a plurality of stops, and the plurality of stops may be positioned asymmetrically about a line along the axis of rotation of the rotor and may have the same dimensions as each other. This may allow for different degrees of rotation around the axis of rotation and improved manufacturing efficiency.

In an embodiment, a portion of the rotor comprising the surface of the rotor facing towards the axis may be attached to the remainder of the rotor by a compliant mechanism for reducing impact on the rotor upon contact with the surface of the stop facing away from the axis. This may reduce the impact shock of the rotor as it contacts the stop and provide additional stored energy for overcoming contact stiction.

In an embodiment, a portion of the stop comprising the surface of the stop facing away from the axis may be attached to the remainder of the stop by a compliant mechanism for reducing impact on the rotor upon contact with the surface of the stop facing away from the axis. This may reduce the impact shock of the rotor as it contacts the stop and provide additional stored energy for overcoming contact stiction.

According to another aspect there is provided a method of manufacturing a micro-electro-mechanical device, the method comprising: disposing a first layer for forming a stator structure on a base layer, and etching into the first layer to form the stator structure and at least one stop, where the stop comprises a trench formed by aspect ratio-dependent etching with walls bounding a landing site at the base of the trench, the stop is formed a distance away from an axis of rotation of a rotor such that on rotation of the rotor about its axis the base of the trench is contacted by the rotor before any other features of the device.

In an embodiment, the method may comprise disposing a second layer for forming a rotor; and etching into the second layer to form a rotor having an axis of rotation and comprising a protrusion dimensioned to make contact with the base of the trench.

In an embodiment, the etching into the first layer may comprise etching the trench with a length at least three times its width. This may allow for more efficient control of the dimensions of the trench formed due to aspect ratio-dependent etching (ARDE).

In an embodiment, the etching into the first layer may be by deep silicon etching. Thus the process of forming the trench may be easily incorporated into the device manufacturing processes.

In an embodiment, the etching the second layer may comprise forming the protrusion as one or more cantilevers of the rotor. In an embodiment, the etching the second layer may comprise forming the protrusion as a plurality of cantilevers where at least one of the cantilevers is joined at a distal end to at least one other cantilever to form an enclosed void therebetween. The joined cantilevers may provide a box section, increasing the effective lateral stiffness compared to the individual cantilevers without the link. The link is spaced away from the stop part so that it does not make contact when the rotor moves either laterally or rotationally.

According to another aspect there is provided a micro-electro-mechanical device comprising at least two rotor portions arranged to rotate around respective axes, the device comprising: at least one of a first stop type disposed in a stator structure layer for limiting the out-of-plane rotational motion of a first rotor portion, the at least one first stop type positioned such that on rotation of the first rotor portion about its respective axis the initial point of contact is between a surface of the at least one first stop type facing away from the respective first axis and a surface of the first rotor portion facing towards the respective first axis; and at least one of a second stop type disposed in a stator structure layer for limiting the rotational motion of a second rotor portion, the at least one second stop type positioned such that on rotation of the second rotor portion about its respective second axis the initial point of contact is between a landing site at the base of a trench of the at least one second stop type formed by aspect ratio-dependent etching and a protrusion of the second rotor portion.

### BRIEF DESCRIPTION OF THE FIGURES

The present disclosure will now be described by way of example with reference to the accompanying drawings. In the drawings:

FIGS. 1a-1e show a simplified MEMS micromirror device.

FIGS. 2a-2d show a simplified MEMS micromirror device.

FIGS. 3a-3f show a simplified MEMS micromirror device.

FIG. 4(a) and 4(b) show SEM micrographs showing a cross-section image illustrating aspect ratio-dependent etching.

FIGS. 5a-5d show a MEMS device with an out-of-plane rotation stop of a first type.

FIG. 6 shows the geometry in cross-section for the portion of the rotor to the right of the axis of rotation.

FIGS. 7a-7f show cross-sections taken across the B-B line in FIG. 5a illustrating various height differences between the stator and rotor.

FIGS. 8a-8e show a plurality of possible arrangements to add compliance.

FIG. 9 shows a plan view of a second type of out-of-plane rotational stop.

FIGS. 10a-10f show a plurality of cross sections of the MEMS device shown in plan in FIG. 9.

FIG. 11 shows an example MEMS device similar to that in FIG. 9.

FIGS. 12a-12c show a plurality of cross sections of the example MEMS device shown in plan in FIG. 11.

FIGS. 13a-13h show a plurality of different protrusion arrangements suitable for implementing the proposed out-of-plane rotational stop.

FIG. 14 shows a schematic diagram of an example process flow used to manufacture the proposed stop.

FIG. 15 shows a schematic diagram of an example process flow used to manufacture the proposed stop.

FIG. 16 shows an example MEMS device comprising a plurality of axis for out-of-plane rotation and respective rotating portions.

FIG. 17 shows an example of a gimballed two-dimensional (2D) mirror geometry which is suitable for operation in a linear array comprising examples of the proposed stops.

### DETAILED DESCRIPTION

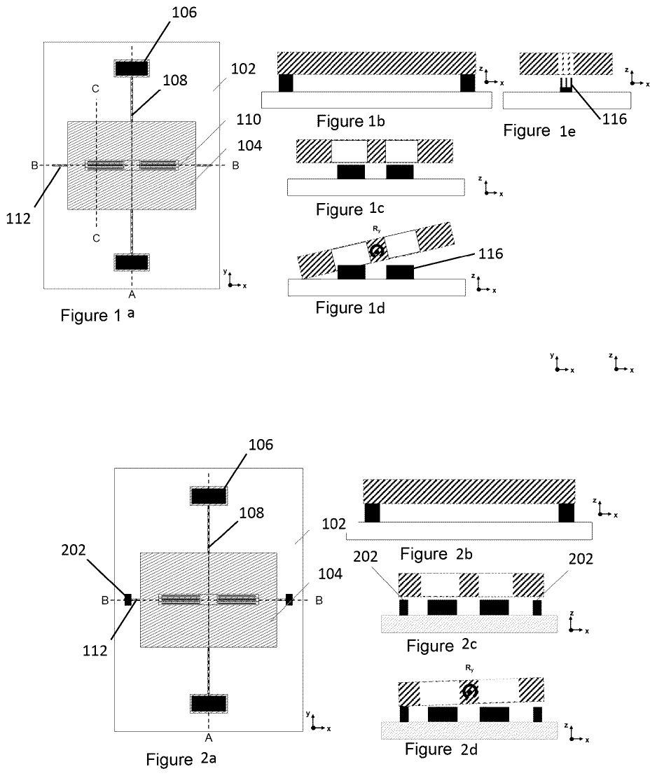

Existing out-of-plane rotational stops may be summarised in reference to three categories in the context of an electrostatic MEMS micromirror. All of FIGS. 1 to 3 show various views and cross sections of a simplified MEMS micromirror device. All comprise a substrate 102, a rotor 104, a pair of anchor points 106, springs 108, a stator structure comprising a drive arrangement 110 for driving the rotor, and a pair of protrusions 112.

Category 1 type out-of-plane stops are illustrated in figures 1a-e. In category 1 type stops, a lower surface of a protrusion 112 (lower when parallel to the substrate 102) contacts an upper surface of a lower layer such as the substrate 102. FIG. 1a shows a plan view of such a MEMS device. Rotation of the rotor occurs around an axis along line A-A. The closed comb drives of the drive arrangement 110 with only three stator comb teeth are for illustration only and details of any compliance structure or isolation are not shown for clarity. That is, any electrical isolation or sub-layers on the substrate are not shown.

FIG. 1b shows a cross section of the device along line A-A. In this example, the springs 108 are integral to the rotor by construction and therefore have the same thickness profile as the main body of the rotor 104.

FIG. 1c shows a cross section of the device along the line B-B. Drive arrangement 110 comprises a drive comb with co-operating teeth and grooves. In FIG. 1c the rotor is parallel to the substrate. Protrusions 112 are integral to the rotor 104 by construction and so in this example have the same thickness profile as the main body of the rotor 104.

FIG. 1d shows a cross section of the device along the line B-B, where the rotor 104 has been rotated until such a time as the lower surface of the protrusion 112 contacts the upper surface of the substrate 102. That is, FIG. 1d shows the same cross section of the device along the line B-B as FIG. 1c but with the rotor 104 in a rotated state about the axis shown, which lies in the y direction as defined in FIG. 1a. Drive arrangement 110 comprising a stator drive comb 116 now overlaps the rotor 104 via co-operating grooves in the main body of the rotor 104.

FIG. 1e shows a cross section of the device along the line C-C. The comb drive 116 of drive arrangement 110 can be seen from an angle which shows the separate teeth of the comb and corresponding grooves in the main body of the rotor 104.

Category 2 type out-of-plane stops are illustrated in FIGS. 2a-d. In category 2 type stops, a lower surface of a protrusion 112 (lower when parallel to the substrate 102) contacts an upper surface of a lower layer such as a stop 202. FIG. 2a shows a plan view of a MEMS device similar to that shown in FIG. 1a with stops 202. Additionally, there is a small gap 204 between a lower surface of the rotor 104 and an upper surface of the stator structure comprising the drive arrangement 110 to ensure that the protrusion 112 touches the stop 202 before the substrate 102 or another part of the stator structure.

FIG. 2b shows a cross section of the device along line A-A. In this example, the springs 108 are integral to the rotor by construction and therefore have the same thickness profile as the main body of the rotor 104.

FIG. 2c shows a cross section of the device along the line B-B, which shows the stops 202 and their relative positioning away from the axis of rotation and stator structure. Drive arrangement 110 comprises a drive comb with co-operating teeth and grooves. In FIG. 2c the rotor is parallel to the substrate but there is a gap between the stator structure comprising the drive arrangement 110 and the rotor 104 main body. Protrusions 112 are integral to the rotor 104 by construction and so in this example have the same thickness profile as the main body of the rotor 104.

FIG. 2d shows a cross section of the device along the line B-B, where the rotor 104 has been rotated until such a time as the lower surface of the protrusion 112 contacts the upper surface of the left-hand stop 202. That is, FIG. 2d shows the same cross section of the device along the line B-B as FIG. 2c but with the rotor 104 in a rotated state about the axis shown, which lies in the y direction as defined in FIG. 2a.

The gap between the stator structure (represented here by the stator comb drive 116), and rotor 104 (when the rotor 104 is parallel to the substrate 102) may be accomplished by having a local recess, either in the stator structure or the rotor 104. If there is no protrusion 112 or an inward facing protrusion, then the stops 202 may be situated closer to the axis of rotation of the rotor 104 to increase the limiting angle. By inward facing protrusion it is meant a protrusion which does not extend out from a point on the outermost edge of the rotor but is located elsewhere on the rotor in relation to the axis of rotation. For example, points inwards from the edge into a void or is located at a different location on the rotor. The trade-off from moving the stop 202 closer to the axis is that this will also increase the impact of gap tolerance and hence increase the limiting angle tolerance. Further, if a large contact area is used, such as a stop post under the main body of a mirror plate, then this increases the risk of stiction. Changing the height of the local gap(s) to increase the angle limit adds manufacturing process complexity.

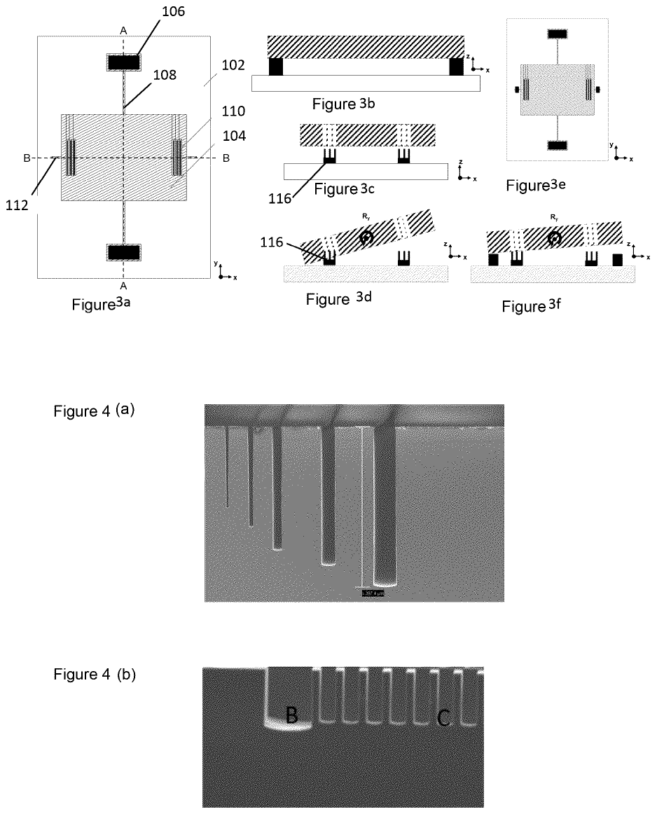

Category 3 type out-of-plane stops are illustrated in FIGS. 3a-f. In category 3 type stops, the long axes of the closed comb drive arrangement 110 of the stator structure are oriented parallel to the axis of rotation A-A of the rotor 104. FIG. 3a otherwise shows a plan view of a MEMS device similar to that shown in FIG. 1a. Rotation of the rotor occurs around an axis along line A-A.

FIG. 3b shows a cross section of the device along line A-A. In this example, the springs 108 are integral to the rotor by construction and therefore have the same thickness profile as the main body of the rotor 104.

FIG. 3c shows a cross section of the device along the line B-B. Drive arrangement 110 comprises a stator drive comb with teeth and co-operating grooves in the rotor 104. The long axes of the stator closed comb drives of the drive structure 110 are parallel to the line A-A and thus parallel to the axis of rotation of the rotor 104. In FIG. 3c the main body of the rotor 104 is parallel with and coplanar to the substrate 102. Protrusions 112 are integral to the rotor 104 by construction and so in this example have the same thickness profile as the main body of the rotor 104.

FIG. 3d shows a cross section of the device along the line B-B, where the rotor 104 has been rotated until such a time as the lower surface of the protrusion 112 contacts the upper surface of the substrate 102. That is, FIG. 3d shows the same cross section of the device along the line B-B as FIG. 3c but with the rotor 104 in a rotated state about the axis shown, which lies in the y direction as defined in FIG. 3a. Drive arrangement 110 comprising a stator drive comb 116 now overlaps the rotor 104 via co-operating grooves in the main body of the rotor 104. However, it can be seen that depending on the relative positioning of the rotor 104 and the drive arrangement 110 from the axis of rotation, and the gap between the rotor 104 and the stator structure as shown in FIG. 3c, the parts of the stator comb drive 116 of the drive arrangement 110 and co-operating grooves in the rotor 104 quickly achieve relative angles which cause collision and thus result in a short circuit.

The above-described configuration means that the gaps between the combs reduce in width as they rotate. Unless the gap between the rotor comb and the stator comb is relatively large there is a risk of a short circuit due to contact before the protrusion contacts the stop. However, increasing the gap reduces the electrostatic actuation generated per comb. This may be countered, either by adding a stop under the protrusion as above, by reducing the stator comb height, by adding a raised landing pad to the substrate, or by adding a protrusion on the underside of the rotor. However, to realise a reduced gap in these ways adds process complexity. Such additional features are not typically able to be added in the same manufacturing step as originally forming the device structures. Another option is to extend the protrusion 112 further from the axis of rotation to reduce the limiting angle. However, this increases the mass moment and may make the protrusion too flexible or fragile at the required length. Additionally, longer protrusions will likely also increase the total chip size and hence the cost.

FIGS. 3e and 3f show the same MEMS device as in FIGS. 3a to 3d, with an addition of two stops under the protrusions 112. FIG. 3e is a plan view of the device with the additional stops. It is easy to see that if the protrusions were extended instead of adding the stops, the whole device footprint could extend beyond the edges of the substrate, thereby requiring a larger chip. FIG. 3f is the same as FIG. 3d but with the additional stops. It is possible to see that in FIG. 3f compared to FIG. 3d, the rotor 104 is prevented from rotating to the point where the comb drive teeth collide with the rotor as it turns. This reduces the amount of overlap within the comb drive, but also prevents short circuits.

Many existing implementations therefore do require additional manufacturing process complexity to realise stop features. For example, defining a gap to a sub-layer or a cap layer typically requires a dedicated patterning cycle, including lithography and etch. This results in extra manufacturing cost and a risk of lower overall yield due to the additional process steps.

Where gaps are small, there is an elevated risk of stiction during processing. If the stop is at an undefined electrical potential relative to the landing site, i.e., floating, it may result in a variable response. If the stop is at a different potential it may result in a short circuit or arcing along with the associated local heating and risk of melting or fusing material. If the contact area is too far above the surface of the substrate, then there is also a risk that the spring restoring forces may be insufficient to overcome in-use stiction. On contact or impact, there is also risk of fracture or chipping where the travel is excessive and the spring restoring force is limited.

The landing area for a protrusion may therefore be at significantly lower height than the foot of the intra-comb region. Thus, there is a risk the intra-comb region will contact before the protrusion on rotation unless it is significantly further from the axis of rotation. A protrusion being elongated and further from the axis of rotation increases the moment of mass, reducing the frequency of operation, and may increase the chip area and cost. Where devices are arrayed, such protrusions may also increase the pitch, limiting the density of devices. By ‘pitch’ it is meant the distance between repeating mirror units in the array. In this case in the direction of arraying, but this could be in 1 or 2 dimensions. Increasing the pitch is bad for a plurality of reasons, for example it increases the chip size and hence cost, and also decreases the fill factor as the non-useful space between mirror elements of the same size increases.

In existing devices, out-of-plane rotation stops are typically only present for a single axis, i.e., Rₓ or R_{y}, even in devices that rotate in two axes.

The presently proposed approach relates to two embodiments of out-of-plane rotational stops, i.e., rotation in Rₓ or R_{y}. The proposed stops require no additional process steps to implement and have multiple applications, for example in a MEMS micromirror with one or more out-of-plane tilt axes.

The first embodiment of rotational stop is based on a gap closing under rotation between two substantially vertical surfaces. The angle of rotation is determined by the in-plane separation between the features and their position relative to the axis of rotation. That is, determined by the size of a gap between the stop and the rotor in a direction normal to the substrate and the distances of the stop and edge of the rotor body from the axis of rotation of the rotor. The gap is measured when the rotor is in an equilibrium state defined by a position to which the rotor is biased by its springs or an equivalent rotational mechanism.

For in-plane stops, it should be noted that for both translational and rotational stops, substantially vertical faces, i.e., faces perpendicular to an extending from the substrate in a direction normal to the substrate, contact each other in the same layer. By the term ‘same layer’, it is meant that contact is made within a plane parallel to the plane of the surface of the substrate. It may similarly be noted that out-of-plane stops are between substantially horizontal surfaces in their unpowered state which are vertically offset, typically in different mask levels and fabricated in different layers. The term ‘unpowered’ here is used in an equivalent manner to the term ‘equilibrium state’. That is, a state in which the rotating mechanical element of the MEMS device is in an undriven state. For example, if a rotor body is attached via springs, then the equilibrium state is the position of the rotor body that those springs bias the rotor body towards in the absence of a driving force, for example, in the absence of an applied force from a comb drive.

The second embodiment of the proposed rotational stop is based on a protrusion moving into an etched feature of a stop such that the stop angle is determined by aspect ratio dependent etching (ARDE) of that feature in combination with the position of the protrusion relative to the axis of rotation.

In one embodiment, the MEMS device uses both types of rotational stop and exploits their relative advantages to realise out-of-plane rotational stops in two orthogonal axes.

Aspect ratio-dependent etching (ARDE), also known as reactive ion etching (RIE) lag, is a well-known phenomenon where higher aspect ratio features etch more slowly than lower aspect ratio features. For example, a high aspect ratio feature such as a trench constrained in one dimension or a hole constrained in two dimensions. This is principally due to transport limitations as the aspect ratio increases, i.e., Knudsen diffusion of chemical species of an etching fluid and the dimensions of the mask. In the deep reactive ion etch process (DRIE), also known as the Bosch process, which comprises a series of repeating etch and deposition steps, it is possible to minimise ADRE at low aspect ratios (<10) by adjusting the associated step parameters. However, this limits the etch rate and selectivity and hence throughput and manufacturability. An example of ARDE can be seen in FIG. 4.

FIG. 4a is an SEM micrograph showing a cross-section image illustrating ARDE in an array of trenches of increasing width from left to right. The depth of the etching is dependent on the width of the trench as defined by the mask.

FIG. 4b is an SEM micrograph showing a stator region or lower comb of a comb drive which illustrates an elevated lower electrode surface in the higher aspect ratio region between the combs ‘C’ compared to the wider, lower aspect ratio region ‘B’.

The two proposed embodiments of out-of-plane rotational stops and their application in an electrostatically-driven MEMS will now be described in more detail. Both stop embodiments use design geometry so that the rotational stop contacts to a region of the same potential when the rotor tilts before contacting other parts of the structure, thus limiting stress in the associated torsion springs and avoiding short circuits. Where the device uses electrostatic comb transducers, no additional process steps are required as the stop may be formed in the same steps used to form the upper (rotor) and lower (stator) combs.

The out-of-plane rotation stop comprising a post (also referred to herein as type A) makes use of a substantially vertical surface of a rotor (when not actuated) and another substantially vertical surface of a stop in a stator ‘layer’, which may be referred to as a post. The stator ‘layer’ is offset from a layer containing the rotor in a direction normal to a substrate of the device. Typically, the stator ‘layer’ is anchored to the substrate. By ‘layer’, it is meant a portion of the MEMS device which is manufactured as one or more applied layers onto the surface of a substrate, or the surface of a layer already applied thereto, to form the structure of either a stator component, rotational ‘rotor’ component, or other component of the MEMS device. This may include embodiments formed by multiple etches into the device layer of an SOI wafer. It may also include embodiments where the rotor ‘layer’ is applied by wafer bonding after patterning the stator ‘layer’.

When the rotor is not actuated it is in its equilibrium state. This is a state in which the rotational component of the MEMS device is not being driven or actuated. That is, in its equilibrium state the rotor is not, for example, rotated under a force and against the biasing of a sprung connector to an anchor. This may also correspond to the rotor being substantially in the same plane in which it was manufactured.

The gap between the stop and the rotating portion of the MEMS structure, or rotor, is sized so that on rotation, a surface of the rotor facing towards the axis of rotation is contacted by a surface of the stop facing outwards from the axis of rotation in advance of contact elsewhere. The stop is wholly or partially laterally enclosed by the rotor so that the gap between them is narrowed on rotation. That is, when the rotor is in its equilibrium state, the inward facing surface of the rotor which makes contact with the stop is further from the axis of rotation than the outward facing surface of the stop which makes contact with the rotor.

Thus, the MEMS device comprises a rotor having an axis of rotation along its length, and a stop for limiting the rotational motion of the rotor, the stop positioned such that on rotation of the rotor about the axis the first point of contact is between a surface of the stop facing away from the axis and a surface of the rotor facing towards the axis.

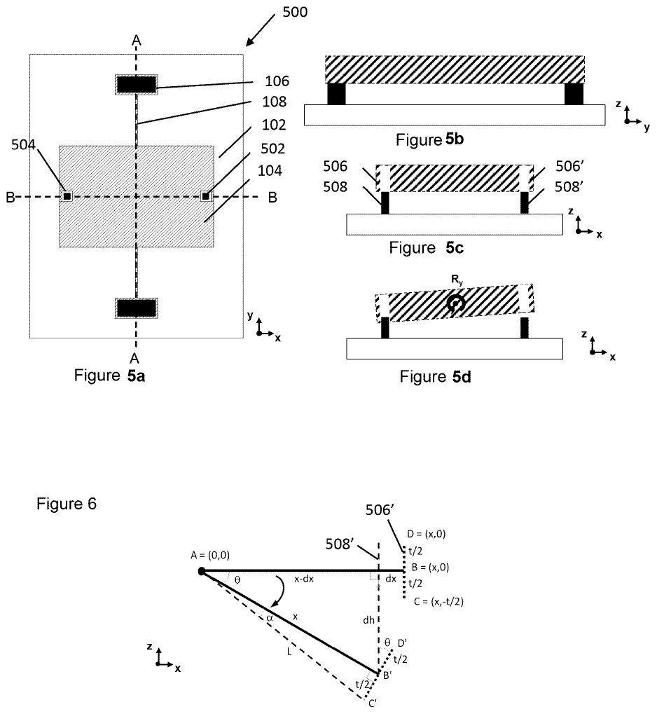

The main features of a MEMS device 500 with an out-of-plane rotation stop of type A as proposed herein, are shown in FIG. 5. FIG. 5a shows a plan view of a MEMS device with the same main structure as devices shown in FIGS. 1-3, and comprises a substrate 102, a rotor 104, a pair of anchor points 106, and springs 108. A drive arrangement for driving the rotor 104 is not shown for simplicity. FIG. 5a additionally shows the specific features of the stop embodiment type A comprising a pair of stops 502 and a corresponding pair of throughways or voids 504 in the rotor 104. The main rotor body 104 rotates about an axis along line AA (in the y direction as defined), and is supported by two torsion springs 108 attached to anchor points 106. Each of the anchors 106 are attached via the stator layer to the base substrate 102. That is, the anchors between the ends of the springs 108 and the substrate 102 are formed out of the same layer(s) applied to the substrate 102 to form the stator structure (not shown). Two stops 502 are also formed in the stator layer and are supported on the substrate base layer 102. Thus, the stop is formed in one or more layers of the device that form a stator structure of the device.

FIG. 5b shows a cross section of the device along line A-A. In this example, the springs 108 are integral to the rotor 104 by construction and therefore have the same thickness profile as the main body of the rotor 104. In an example, the device may comprise at least one spring biasing the rotor to an equilibrium state.

FIG. 5c shows a cross section of the device along line B-B. It can be seen that in this embodiment the rotor 104 and stop 502 do not overlap when the rotatable part of the device or rotor 104 is not rotated. That is, there is no overlap in the labelled z direction, i.e., in a direction extending outwardly from a plane of the substrate 102. The stop may be located such that when the rotor is in its equilibrium state the stop is spaced from the rotor in a direction normal to the substrate. The surface of the stop facing away from the axis may be described as extending outwardly from a plane of a substrate of the device.

FIG. 5d shows a cross section of the device along line B-B. The rotor 104 has been rotated in an anti-clockwise direction about the axis along line A-A parallel to the y-axis, denoted by R_{y}, in the centre of the rotor 104 as illustrated. On rotation, the gap between the side of the stop 502 facing outward from the axis of rotation (506 or 506′) and the inward-facing side of the rotor (508 or 508′) reduces until the lower edge of the inward-facing side of the rotor comes into contact with the stop 502. It should be noted that the inward-facing side of the stop 502 does not contact the rotor 104 before the outward-facing side (assuming the gap is the same on each side) due to the outward-facing side of the rotor being a greater distance from the axis of rotation than the inward-facing side of the stop. The rotor may contact the stop at a region of the stop with the same potential as the rotor.

The dimensions of the device and the positioning of the stop define the angle of rotation prior to contact. Specifically, the angle at which contact occurs is defined by the gap in the x direction between the opposing sides 506 and 508 for anticlockwise rotation or 506′ and 508′ for clockwise rotation; in combination with the distance from the axis of rotation R_{y} in z direction and x direction of the lower edge of 506 or 506′ respectively. These distances are as measured when the rotor 104 in its equilibrium state as shown in FIG. 5c.

FIG. 6 shows the above described geometry in cross-section for the portion of the rotor to the right of the axis of rotation, as shown in FIG. 5c. FIG. 6 considers the case where the rotor is of thickness, t, and extent, 2x, and rotates around the centre of rotation, A. In FIG. 6, B is the position of the midpoint of the rotor (i.e., at half the thickness t/2), C is the lower edge of the rotor surface 506′ facing towards the axis and D is the upper edge of rotor surface 506′ facing towards the axis. When rotated clockwise by an angle θ, C moves to C′ with coordinate ([x.cos θ−sin θ.t/2], −[x.sin θ−cos θ.t/2]). D moves to D′ with coordinate ([x.cos θ+sin θ.t/2], −[x.sin θ+cos θ.t/2]). Thus, the change in x coordinate is larger at C′ than D′. For example, where the gap in x between 506′ and 508′ is 3 μm, A-B is 250 μm and t is 25 μm then this gives a contact angle of approximately 6.5°.

Those skilled in the art will appreciate that the rotor, stator and substrate base may each comprise a single layer or a plurality of different layers. Similarly, although shown as identical, the gap 506-508 and 506′-508′ may also be different and/or the stop may be located a different distance from the axis of rotation on each side to provide different stop angles for clockwise and anti-clockwise rotation. Likewise, a single rotational stop or a plurality of rotational stops may be used.

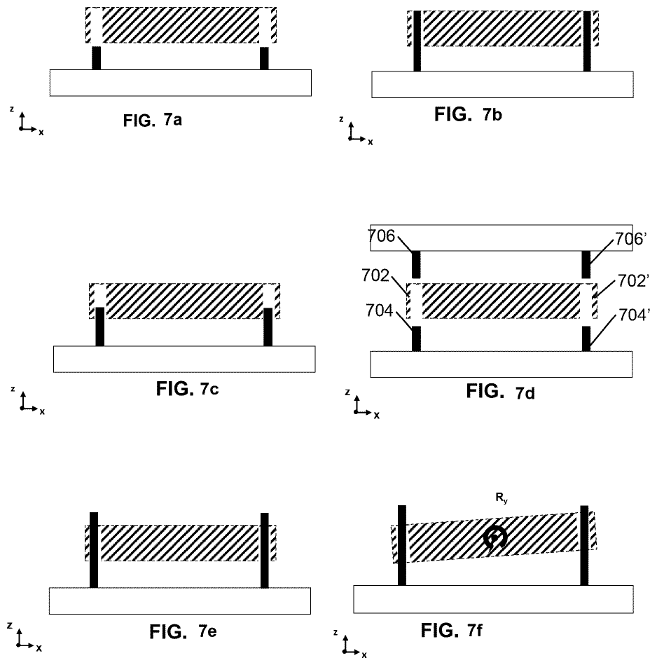

FIG. 5 shows an example of the main embodiment of the out-of-plane rotation stop type A. There are many possible variations around this main structure. Specifically, those where the stator ‘layer’ may have various height differences compared to the rotor ‘layer’. Examples of these are shown as cross-sections in FIGS. 7a-f taken across the B-B line of the plan view as shown in FIG. 5a.

FIG. 7a shows an example embodiment of the proposed stop which has a gap between the stop and the rotor (i.e., in the z direction as defined in the figure). That is, the stop is located such that when the rotor is in the equilibrium state the stop is spaced from the rotor in a direction normal to the substrate. This vertical offset (gap in the z direction) should not be so large that, for the specified gap in the x direction as described above, the rotor and stop side surfaces are no longer the initial point of contact on rotation of the rotor. The gap or space in a direction normal to the substrate is able to be realised in a standard SOI MEMS mirror process flow by etching a shallow recess in the lower SOI prior to the COMB1 definition in regions where it is not to be bonded to the upper SOI. The contact points and limits are as in the main embodiment depicted in FIG. 5.

In some embodiments there may be a partial overlap between the layers in a direction normal to the substrate. That is, when the rotor is in an equilibrium state, the device layer forming the rotor may overlap the stator ‘layer’ comprising the stop such that at least part of the stop is located within a throughway of the rotor. This throughway, as defined by the rotor, e.g., by a void or trench within or formed by an extension of the rotor, in turn defines the inward facing surface of the rotor which, on rotation of the rotor, contacts the stop. In such an embodiment, and by way of this partial overlap, the rotational stop may also act as an in-plane lateral translation stop in addition to a rotational stop when the rotor is not rotated, i.e., in an equilibrium state. It can therefore be said that the rotor defines a throughway in which at least part of the stop is located.

FIG. 7b shows an example embodiment where the stator ‘layer’ has an upper surface which is level with the upper surface of the rotor. That is, the top of the stop, i.e., the surface of the stop furthest from the substrate and formed by the stator structure ‘layer’, is the same distance from the substrate as the upper surface of the rotor. In other words, the stop is located such that when the rotor is in an equilibrium state the stop overlaps the rotor in a direction normal to the substrate. Specifically, in this embodiment the stop fully overlaps the rotor. As a consequence, the surfaces of the rotor and the stop furthest from the substrate are co-planar. This configuration may be realised when the upper SOI is bonded to the lower SOI in the process flow and where a recess is not present. For example, as is used when forming the stator as well as the anchor.

FIG. 7c shows an example embodiment where the stop partially overlaps the rotor. That is, the stop is located such that when the rotor is in an equilibrium state the stop overlaps the rotor in a direction normal to the substrate. The top of the stop, i.e., the surface of the stop furthest from the substrate and formed by the stator structure ‘layer’, is further from the substrate than the lower surface of the rotor. In practice this may be realised in the same flow as described in reference to the embodiment of FIG. 7b, but with an additional process cycle to etch a recess into the stator layer and reduce the height of the stop from the top surface of the rotor.

FIG. 7d shows an example embodiment comprising a cap wafer or cap portion with stops formed therein to allow for bidirectional drive. For example, an option of having a further comb drive to allow bi-directional local drive may then be implemented. The lower portion of this example embodiment is identical to the example embodiment shown in FIG. 7a. Thus, the micro-electro-mechanical device may comprise a cap portion comprising one or more stops configured to align with one or more stops extending in a direction normal to the substrate, and the cap may be positioned in an inverted orientation above the rotor. The cap feature also provides the option to have wafer-scale hermetic or vacuum sealing for the MEMS device (not shown).

The addition of a cap portion adds another contact point and therefore requires a stop as part of the upper stator structure in addition to the lower stop(s). These can be aligned if the gaps and axial distances are the same on rotation, i.e., those between elements 702 to 704 and 702′ to 706′ for counter-clockwise rotation and 702 to 706 and 702′ to 704′ for clockwise rotation. In practice, the alignment of the lower stator structure comprising the stops and the rotor may be achieved using conventional photolithography to a common reference alignment mark. Aligning the upper stator structure comprising the stops to the rotor may need to rely on bond alignment which typically has the drawback of poorer alignment accuracy. Thus, in reality the gaps may be slightly different. Those skilled in the art will realise that the equivalent stator structures comprising stops as depicted in FIGS. 5, 7b and 7c may also be realized on a cap portion.

FIGS. 7e and 7f show an example embodiment where the stop(s) extend in a direction normal to the substrate such that the stop(s) extend further from the substrate than the rotor. The stop therefore overlaps the rotor and extends further still out of the other side of the rotor. In other words, the stop is located such that when the rotor is in an equilibrium state the stop extends further from the substrate than the rotor. The top surface of the stator structure, and therefore the upper surface of the stop, is above the rotor top surface. Thus, the rotor contacts the stop once above the axis of rotation and once below the axis of rotation as in FIG. 7d. Therefore, if the stop is sufficiently above the rotor, the stop again contacts on both sides.

FIG. 7e shows the rotor in its equilibrium state, with the two stops shown extending in a direction normal to the substrate and protruding from the other side of the rotor. The stop therefore passes all the way through the throughway when the rotor is in its equilibrium state.

FIG. 7f shows the same embodiment as shown in FIG. 7e, but with the rotor rotated anti-clockwise around the indicated axis of rotation, e.g., along line A-A in FIG. 5 and parallel to the y-axis, as denoted by R_{y}. As a result, the right-hand stop is contacted on a surface facing away from the axis of rotation by the top edge of a surface of the rotor facing towards the axis. The stop is located in a throughway of the rotor located on the right-hand side of the axis as illustrated. The left-hand stop is also contacted on a surface facing away from the axis of rotation, but by the bottom edge of a surface of the rotor facing towards the axis. The stop is located in a throughway of the rotor located on the left-hand side of the axis as illustrated.

To contact at both locations simultaneously or at similar instances and with similar force, the stops may be substantially symmetrically positioned about the axis of rotation, as in the examples shown. For example, if the micro-electro-mechanical device comprises a plurality of stops, the plurality of stops may be positioned symmetrically about a line along the axis of rotation of the rotor and having the same dimensions as each other. That is, the stops may extend in a direction normal to the substrate the same amount, have the same width, and/or have an outward facing surface the same distance from the axis of rotation of the rotor. A plurality of stops may be disposed within the stator structure so as to make contact with the rotor on rotation in a plurality of directions.

It should be understood that the proposed out-of-plane rotational stop may be implemented in a non-symmetrical manner. That is, stops may be positioned asymmetrically about the axis of rotation of the rotor. Stops may have contact points on surfaces facing away from the axis of rotation of the rotor at different distances from the axis and different distances in a direction normal to the substrate. Therefore, where the micro-electro-mechanical device comprises a plurality of stops, the plurality of stops may be positioned asymmetrically about a line along the axis of rotation of the rotor and may have the same dimensions as each other.

Similarly, asymmetrically positioned stops may also have different dimensions to each other. Therefore, where the micro-electro-mechanical device comprises a plurality of stops, the plurality of stops may be positioned asymmetrically about a line along the axis of rotation of the rotor and at least one stop of the plurality of stops may have different dimensions (i.e., compared to the one or more other stops). As such, different angles of rotation of the rotor and structure configurations may be realised. Symmetrical stop configurations may be advantageous for minimising torsional stresses and induced torsion on rotor components under shock and vibration by balancing mass moments about the axis of rotation.

The embodiment of FIGS. 7e and 7f may be realised in the same type of process flow as for the embodiment shown in FIG. 7b, but with an additional process cycle to thin the rotor. Thus, offering the same alignment tolerance between the rotor and stop both above and below the rotational axis of the MEMS device.

In some embodiments the stop structure may be narrowed in the contact region. This can provide additional compliance. The stop may be locally undercut (e.g., in the release process), whilst the remainder of the feature remains anchored to reduce shock impact. In some embodiments the stop or a portion thereof may have additional compliance features to reduce shock impact upon contact with the rotor. That is, a portion of the stop comprising the surface of the stop facing away from the axis may be attached to the remainder of the stop by a compliant mechanism for reducing impact on the rotor upon contact with the surface of the stop facing away from the axis.

Similarly, in some embodiments the portion of the rotor that makes contact with the stop may have additional compliance features to reduce shock impact. For example, a compliant portion of the rotor may be supported and connected by springs to the main rotor body.

The above proposed embodiments are of a post-in-hole type concept. Those skilled in the art will appreciate that there are many possible implementations and variations of this arrangement. Building in additional compliance at contact points may reduce the impact shock by storing some energy and using that stored energy to help overcome any stiction forces. Moving from an edge-to-face contact to a face-to-face contact may reduce contact stress. Such compliance mechanisms may be on the rotor, the stop structure, or both.

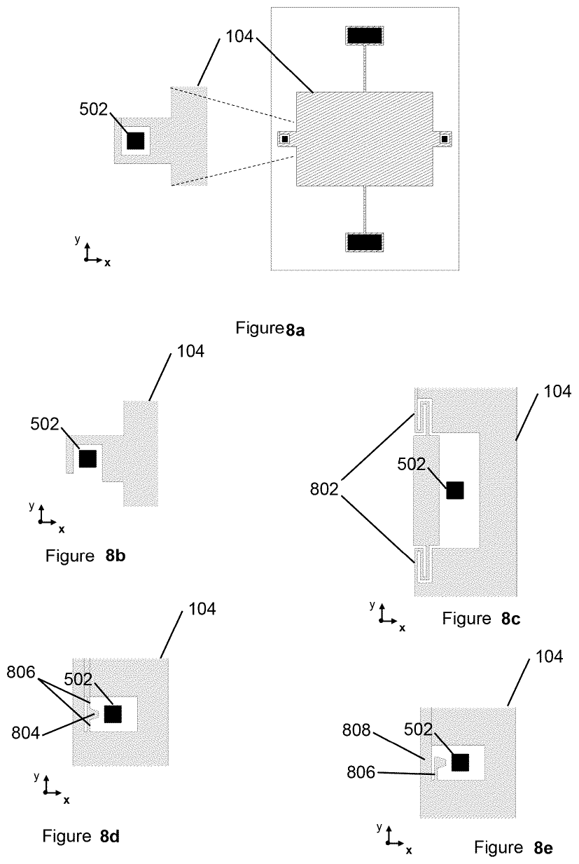

As the stop is anchored to the substrate, it is normally most practical to introduce compliance into the rotor. Possible arrangements include, but are not limited to, the examples to add compliance shown in FIGS. 8a to 8e. Those skilled in the art will appreciate that these are generic and the lengths and widths of the features may be tailored to achieve the required compliance. Similarly, the gaps and position can be tailored to achieve the required angle. It should be noted that gaps around the stator stop do not need to be the same as the target stator-rotor gap between the contact faces. It should also be understood that the compliance mechanism may be introduced to the stop itself, either as an alternative or in combination with compliance in the rotor. For example, this may be the case where a very narrow region of the stop has been undercut in the release etch step of manufacturing.

FIG. 8a shows a plan view of a MEMS device with a U-shaped portion of the rotor comprising the surface which contacts the stop 502. The rotor 104 defines a throughway in which the stop is located. The stop makes contact with a surface of the rotor facing towards the axis of rotation of the rotor inside the throughway. That is, the stop makes contact with an internal surface of the throughway of the rotor. The surface may in fact be contacted on an edge of said surface, as illustrated and described above in reference to FIGS. 5, 6, and 7. A compliance mechanism is built into a portion of the rotor where it contacts the stop. The portion of the rotor with the compliance is shown in a zoomed detail to the left of FIG. 8a. In this arrangement the stop 502 contacts the rotor 104 on the periphery at the portion of the rotor in the form of a U-shape. The compliance is formed by the portion of the rotor at the periphery of the rotor main body having a bendable structure. The throughway defined by the rotor has a portion that makes contact with the stop which is able to flex on impact more than the remainder of the rotor body due to its comparatively narrower proportions. For example, the sides of the protrusion within which the throughway is located are thin compared to the width of the rotor body. In this way some physical flexibility is possible in this portion of the rotor when the stop contacts the surface of the rotor facing towards the axis. Therefore, a portion of the rotor comprising the surface of the rotor facing towards the axis may be attached to the remainder of the rotor by a compliant mechanism for reducing impact on the rotor upon contact with the surface of the stopper facing away from the axis.

FIG. 8b shows a zoomed detail of a plan view of a MEMS device similar to that shown in FIG. 8a. However, in this example there is a hook shaped portion of the rotor 104 comprising the surface which contacts the stop 502. The compliance mechanism is built into the portion of the rotor which contacts the stop, but instead of a flexible portion, one side of the portion is absent in comparison to the structure of FIG. 8a. This configuration is considerably more compliant than the U-shape configuration of 8a. All other features of the rotor and stop are the same as described in relation to FIG. 8a.

FIG. 8c shows another zoomed detail of a plan view of an example MEMS device. However, in this arrangement the surface on the rotor 104 which contacts the stop is supported by serpentine springs 802 for added compliance. The serpentine springs add compliance in x directions in the plane of the main body of the rotor but also offer further compliance at the contact region to allow face-to-face contact through rotation in R_{y}. That is, the serpentine springs allow for some rotation of the compliant portion of the rotor which comprises the surface which contacts the stop such that instead of an edge-to-face type contact, the surface of the rotor may rotate to enable a face-to-face type contact between the stop and the rotor. This configuration may also comprise differently sized gaps between the non-contacting surfaces of the throughway and the stop. Specifically, gaps between such surfaces and the stop may be greater than between the contacting surface and the stop. This may ensure that, in light of the compliance and resulting movement afforded to the rotor portion which contacts the stop, that the rotor still contacts the intended surface of the stop facing away from the axis before any other part of the stator structure. All other features of the rotor and stop may be the same as described in relation to FIG. 8a.

FIG. 8d shows another zoomed detail of a plan view of an example MEMS device.

In this arrangement the rotor stop 502 comprises a low surface area protrusion 804 supported on either side by a pair of beams forming a bridge 806. That is, the protrusion provides a surface with a smaller contact area on the rotor where it contacts the stop. The compliance is provided by the flexing of the bridge into the gap behind between the protrusion and the outermost edge of the rotor form the axis. Adding such a protrusion to provide a reduced surface area for contact with the stop may be used in combination with any of the compliance designs shown in FIG. 8. Similarly, it should be understood that other similar compliance designs for use with the proposed out-of-plane rotational stop may also incorporate such a protrusion to reduce the surface area of the contact surface of the rotor. A bridge beam support may offer additional compliance in both x directions in the plane of the main body of the rotor 104 and rotationally in R_{y}, the degree of which may be adjusted depending on the dimensions of the beam. The wider beam behind 808, forming the outer edge of the rotor in FIG. 8 d, may allow for a second contact to be made for a staged stop. Alternatively, no wider beam may be present, or a larger gap between the beam comprising the protrusion and the wider beam behind may be used to prevent a second contact. In some examples the wider beam may not comprise an outer edge of the rotor.

FIG. 8e shows another zoomed detail of a plan view of an example MEMS device. In this arrangement the rotor 104 comprises a low area protrusion as in FIG. 8d, but this protrusion is supported by a single beam or cantilever 806. The cantilever offers increased compliance compared to the torsion bridge. The wider beam behind 808, when present, allows a second contact to be made for a staged stop.

Those skilled in the art will appreciate that in-plane motion may also be limited by the use of conventional lateral in-plane stops in combination with the above-described rotational stop. Such conventional stops may also include a degree of compliance to reduce impact shock and are typically implemented between vertical faces in the same layer. Usually contact to conventional lateral stops is only made under high shock loads when unpowered, i.e., when a rotational element of the device is not rotated or is in an equilibrium state. In this scenario, the rotor and rotational stop in the stator structure should not make contact when the conventional lateral stop is contacted, i.e., a lateral gap between the rotational stop and the rotor should be larger than a lateral gap between the conventional lateral motion stop plus any additional lateral motion allowed due to compliance in the lateral stop. When the term lateral gap or lateral motion is used this is a gap or motion in a plane or direction parallel to the plane of the substrate, or in x and/or y directions as defined above. Advantageously, the formation of such conventional lateral stops may be incorporated in the existing process flow for manufacturing the proposed rotational stop without additional process complexity. That is, they may be formed in the same process steps as the rotor and stator structures.

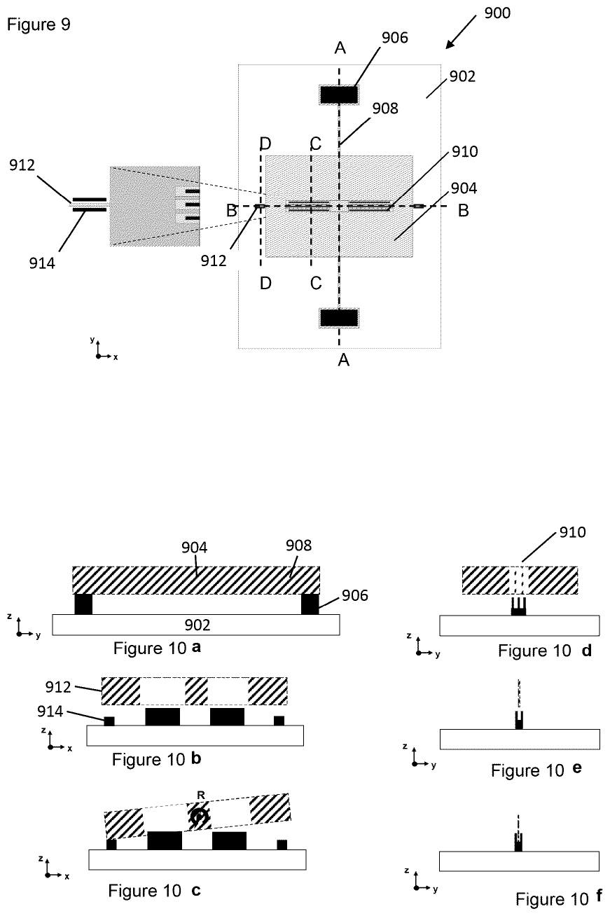

FIG. 9 shows a plan view of a further example of an out-of-plane rotational stop. Out-of-plane rotational stops of this type (also referred to herein as type B) are formed between a substantially horizontal surface of a rotor layer to another substantially horizontal surface in another layer, e.g., the stator layer, offset in the vertical plane from the rotor layer. Specifically, a protrusion from the main body of the rotor which sits within a trench or hole in the stator layer forming the stop. The stop has an aspect ratio defined during formation by dry etching in the second layer such that the stop is equal to or higher than any other regions in the stator layer under the rotor. That is, the etched depth providing the base of a trench of the stop feature is less than or equal to other portions of the device so that the rotor contacts this portion of the stop before other regions of the device (e.g., in pull in) when the rotor layer tilts. This may include embodiments formed by multiple etches into the device layer of an SOI wafer. It may also include embodiments where the rotor ‘layer’ is applied by wafer bonding after patterning the stator ‘layer’ or embodiments where the substrate under the stator ‘layer’ is also patterned by etching.

When the term ‘horizontal’ is used in the present description it is in reference to the rotor being in an equilibrium state as defined above. This may correlate with the rotor being ‘horizontal’ in reference to the plane of the substrate or base of the MEMS device. However, it should be understood that in some device designs which make use of the presently described out-of-plane rotational stop, a rotor in its equilibrium state may not be ‘horizontal’ or parallel to all or any one of the plane of the substrate or base of the device, or the plane of a further layer disposed on the substrate or base upon which a stop has been formed. That is, a state of equilibrium of the rotor may not necessarily be able to be described as ‘horizontal’, nor required to be as such, in order for the proposed out-of-plane rotational stops as described herein to be implemented.

In relation to the stator layer, stop of the stator layer, stop layer, or base of the trench of the stop, the term ‘horizontal’ is used herein in reference to the plane of the substrate or base of the MEMS device, or the plane of a further layer on which the stop has been formed which has been disposed on the substrate or base; i.e., when one of these or other features of the device, which are not able to rotate like the rotor, are said to be ‘horizontal’, they are substantially parallel to a plane of the substrate or base of the device. In other words, a horizontal feature may lie at the same value on a z axis which is normal to the plane of the surface of the substrate or base defining an xy plane.

FIG. 9 shows a plan view of the main features of an example MEMS device 900 with an out-of-plane rotation stop of type B. The device comprises a substrate 902, a rotor 904, a pair of anchor points 906, springs 908, a drive arrangement 910 for driving the rotor, and a pair of protrusions 912. The device may comprise one or more springs biasing the rotor to an equilibrium state. A lower surface of the protrusion 912 contacts an upper surface of a stop 914 (i.e., in a stator structure layer) on a lower layer such as the substrate 902. Rotation of the rotor 904 occurs around an axis along line A-A. The stop 914 comprises a high aspect ratio trench. The protrusion 912 is arranged to pass down into the trench such that it may contact the base of the trench. The closed comb drives of the drive arrangement 910 with only three stator elements per side are for illustration only and details of any additional compliance structure or isolation thereof are not shown for clarity.

On the left-hand side of FIG. 9 there is a zoomed section of the plan view. The zoomed section shows the indicated area at the edge of the rotor 904 comprising the protrusion 912 orientated above the trench of the stop 914, either side of the trench of the stop 914 is visible to the sides of the protrusion 912.

The stator region around the rotor protrusion 912 is of equal or higher aspect ratio than the stator comb of the drive arrangement 910. This means where the protrusion will land will have etched to a lesser depth due to ARDE than the intra-comb base of the stator structure, which is typically the next highest aspect ratio feature on such a device.

The high aspect ratio trench is defined during manufacture. The method of manufacture comprises disposing a first layer for forming a stator structure on a base layer, and etching into the first layer to form the stator structure and at least one stop, where the stop comprises a high aspect ratio trench compared to the rest of the stator structure, whereby as a result of aspect ratio-dependent etching the stop is provided with walls bounding a landing site at the base of the trench which is equal or greater in distance from the substrate than any other features of the stator structure. The first layer, or stator layer as described above, may comprise a plurality of sublayers which have been disposed and built up to provide the stator layer as a whole. The stator layer therefore comprising one or more disposed sublayers from which the stator structure is formed.

The method may additionally comprise disposing a second layer for forming a rotor and etching into the second layer to form a rotor having an axis of rotation and comprising a protrusion dimensioned to make contact with the base of the trench prior to any other region of the device on rotation of the rotor about its axis of rotation. The etching the second layer may comprise forming the protrusion as one or more cantilevers of the rotor. Additionally or alternatively, the etching the second layer may comprise forming the protrusion as a plurality of cantilevers. Further, at least one of the cantilevers may be joined at a distal end to at least one other cantilever to form an enclosed void therebetween.

FIGS. 10a-f show a plurality of cross sections of the MEMS device shown in plan in FIG. 9.

FIG. 10a shows a cross section of the MEMS device shown in FIG. 9 along line A-A and comprises the anchor points 906, the rotor 904, and the springs 908. The springs 908 are integral to the rotor 904 by construction and therefore have the same thickness profile as the main body of the rotor 904.

FIG. 10b shows a cross section of the MEMS device shown in FIG. 9 along line B-B illustrating the stator arrangement 910 (comprising two opposing comb drives), the protrusions 912, and the stops 914. As the protrusions are integral to the rotor body, these features have the same thickness profile along the line B-B. On each side of the rotor, there is a gap between the rotor comb and the stator comb structures of the drive arrangement 910, and another gap between the protrusions 912 and the stops 914. The rotor is shown in its equilibrium state. The equilibrium state is the position the rotor is biased towards by the springs. In this example, that is when the rotor is horizontal, i.e., the plane of the rotor is parallel to the substrate of the device and the upper surface of the stator structure (the upper surface of the stator structure being the surface of the stator structure furthest from the substrate). It should be understood that in some examples the upper surface of the stator structure may not be parallel to the substrate.

FIG. 10c shows the same cross section of the MEMS device shown in FIG. 9 along line B-B as FIG. 10b. However, in this cross section the rotor is rotated in an anti-clockwise direction. It can be seen that the rotor has contacted the stator structure where the protrusion meets the stop. The respective parts of the drive arrangement 910 are partially interleaved, with the stator comb and rotor comb overlapping but not making contact with each other. The void in the rotor body indicates the location of the rotor comb of the drive arrangement 910.

FIG. 10d shows a cross section of the MEMS device shown in FIG. 9 along line C-C. This cross section shows the drive arrangement 910 and the respective combs on the rotor and the stator structure. The combs allow for a force to be applied between the rotor and the stator structure due to a potential difference between them. It may be understood from this figure that rotation of the rotor comb could continue until it makes contact the bottom of the stator comb between its teeth in the absence of a rotational stop. This contact would stop the comb drive from working as the potential difference generating electrostatic torque would be lost due to the resulting short circuit with associated significant local heating and damage to the device.

FIG. 10e shows a cross section of the MEMS device shown in FIG. 9 along line D-D. This cross section shows the protrusion 912 and stop 914 features. It can be seen that the protrusion 912 is dimensioned to contact the base of the trench of the stop 914 when the rotor 904 rotates. FIG. 10f shows the same cross section of the MEMS device shown in FIG. 9 along line D-D as in FIG. 10e but when rotor is rotated.

Cross-sections along lines C-C and D-D show the differences between the etch depths of the different features based on their respective widths due to ARDE. This difference ensures the protrusion will contact the stop before other parts of the rotor as shown in FIGS. 10c and 10f, by ensuring the depth of the stop etch is less than the etch of the comb drive teeth. Advantageously, the landing site may be located further from the axis of rotation than other feature locations which could make contact, such as the intra-comb base. Similarly, the landing site may advantageously be at the same electrical potential as the rotor protrusion.

For the high aspect ratio region defining the trench of the stop feature, the length should be long enough to ensure the aspect ratio, and hence etch rate, may be determined by the width. Thus, as part of the method of manufacture, etching into the first layer may comprise etching the trench with a length at least three times its width. For a trench to be well defined by aspect ratio dependent etching, the length should preferably be in the region of 10 times the width. In an example, the trench feature may be formed by deep silicon etching, also known as deep reactive ion etching (DRIE). For example, this may be in a Bosch process or cryogenic process.

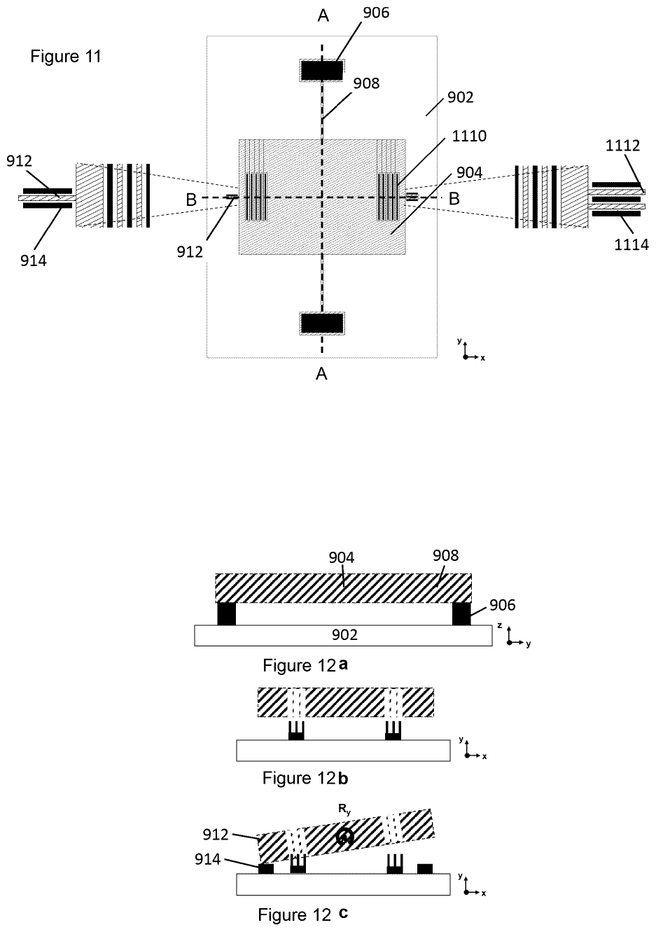

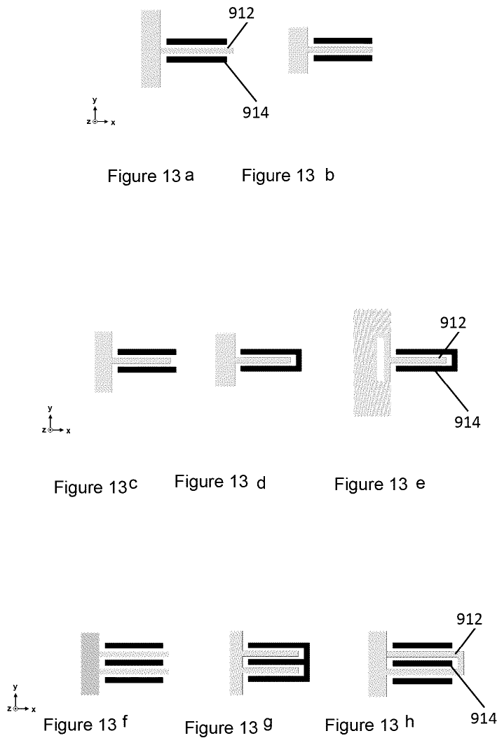

FIG. 11 shows an example MEMS device similar to that in FIG. 9. However, in this example the drive combs are oriented with their long axis parallel to the axis of rotation. As in FIG. 9, the left-hand stop comprises a single protrusion (or cantilever protrusion), configured to contact a high aspect stator stop region. However, the right-hand stop in FIG. 11 comprises an array of protrusions (or cantilever protrusions), each configured to contact an associated high aspect stator stop region. FIG. 11 illustrates that different kinds of protrusions may be used with a high aspect stop region. Multiple examples of such protrusion and stop combinations are shown in FIG. 13. Those skilled in the art will realise that devices may contain multiple protrusions at a variety of locations. In practice, symmetrical stop arrangements are preferred so the centre of mass remains on the rotation axis to reduce sensitivity to shock and vibration. However, symmetrical arrangements are not required to implement and benefit from the advantages of the out-of-plane rotation stops proposed herein.

FIG. 12a shows a cross section along line A-A of the MEMS device shown in plan in FIG. 11. The device comprises the anchor points 906, the rotor 904, and the springs 908. The springs 908 are integral to the rotor 904 by construction and therefore have the same thickness profile as the main body of the rotor 904.

FIG. 12b shows a cross section of the MEMS device shown in FIG. 11 along line B-B illustrating the drive arrangement 1110 (comprising two opposing comb drives), the protrusions 912 and 1112, and the stops 914 and 1114. As the protrusions are integral to the rotor body, these features have the same thickness profile along the line B-B. There is a gap between the rotor and the stator structure portions of the drive arrangement 910, and between the protrusions 912, 1112 and the stops 914, 1114. The rotor is shown in its equilibrium state. The equilibrium state is the position the rotor is biased towards by the springs. In this example, that is when the rotor is horizontal, i.e., the plane of the rotor is parallel to the substrate of the device and the upper surface of the stator structure (the upper surface of the stator structure being the surface of the stator structure furthest from the substrate). It should be understood that in some examples the upper surface of the stator structure may not be parallel to the substrate. Different to the cross section along B-B in FIG. 10b above, the high aspect ratio of the comb drive components in the stator structure can be seen due to the rotated orientation of the comb drive compared to the example in FIGS. 9 and 10.

FIG. 12c shows the same cross section along line B-B of the MEMS device of FIG. 11 as shown in FIG. 12b. However, in this cross section the rotor is rotated in an anti-clockwise direction. It can be seen that the rotor has contacted the stator structure where the protrusion meets the stop. The respective comb drives of the drive arrangement 910 are partially interleaved, with the stator comb and rotor comb overlapping but not making contact with each other. It can be seen that the range of angles through which the rotor may move before contacting the stator comb in this configuration may be more limited than in the configuration shown in FIG. 9. This is due to the effective narrowing of the gaps between the rotor comb teeth as the rotor rotates. The more the rotor rotates, the narrower the gaps become, and thus, if the gap is insufficient, the rotor may contact the sides of the stator comb teeth before it contacts the base between the stator comb teeth. Therefore, it can be seen that it is important to position the stator stop such that the first point of contact between the rotor and the stator structure or another lower layer is between the one or more stator stop trenches and the respective rotor protrusions.

The width of the protrusion may be limited by the width of the high aspect ratio trench and the lateral gap required between the protrusion and the sides of the trench. In examples where there is a second axis of rotation possible (an example of this is explained in more detail below), then the lateral gap between the protrusion and the side of the trench may also need to account for the rotation of the rotor in a second axis parallel to the length of the protrusion. This is because a rotation of the protrusion along its length, i.e., in an axis parallel to its longest dimension, has the effect of widening the profile of the protrusion when viewed from above, and thus a wider trench is required when the rotor is also rotated around the first axis.

Advantageously the protrusion is at a larger extent from the axis of rotation than the main body of the rotor (although this is not a requirement) and the contact region in the stator layer should be at the same potential as the rotor to avoid electrical short circuit on contact.

As mentioned above in reference to FIG. 11, the protrusion of the rotor or rotating layer may take the form of a cantilever or a series of cantilevers. That is, depending on the required forces due to contact and the available dimensions of the MEMS device, one or more protrusions may be implemented alongside one or more trenches of a stop feature.

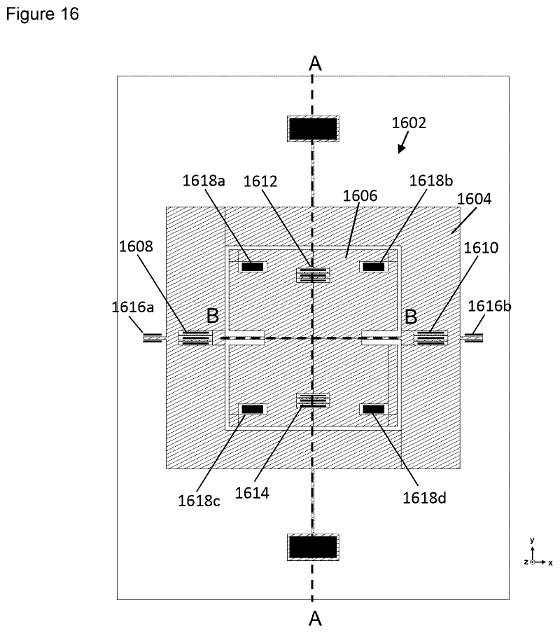

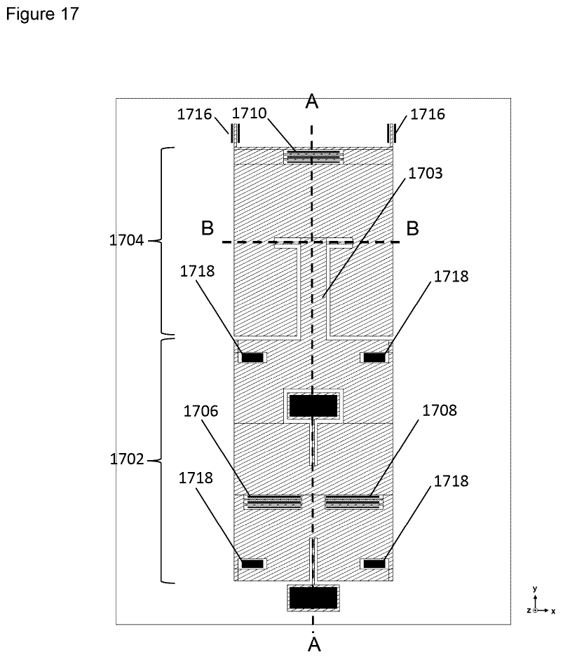

In an example embodiment, in-plane motion may also be limited by using conventional lateral in-plane stops, typically between vertical faces in the same layer. Lateral in-pane stops may also include a degree of compliance to reduce impact shock and aid in overcoming adhesion forces. Typically contact to conventional lateral stops is only made under high shock loads when unpowered, for example when a device is dropped. In this scenario, a gap should remain between the rotor and stator of the rotational stop when the conventional lateral stop gap is contacted. That is, the lateral gap for the rotational stop should be larger than the lateral gap for the conventional stop plus any additional motion due to compliance in the stops. Similarly, if a second axis of rotation affects the rotor protrusion, then the lateral gap should allow for the second rotation also. An example of this second axis of rotation scenario may be seen in FIGS. 16 and 17 and is discussed below.

There are many different potential protrusion arrangements suitable for implementing the out-of-plane rotational stop proposed herein. Examples include those illustrated in FIG. 13 and described below. It should be understood that the core element of the proposed stop feature currently being described is a high aspect ratio etched trench which can be implemented using ARDE during production of the MEMS device with minimal, if any, additional manufacturing processes. Therefore, any arrangement of one or more protrusions which are suitable for use with the proposed ARDE trench stop feature may be implemented.

In an example implementation, the length of the protrusion of the rotor is ideally short enough not to add excess mass moment whilst being long enough to achieve the desired stop rotation angle, which is defined by the protrusion length and the trench depth at contact.

In the examples, the high aspect restriction is principally in a single dimension from features in the stator layer that form a channel or trench. Accessibility of etch species from the ends of the channel may reduce the effective transport restriction associated with the aspect ratio of the channel near those ends. Thus, the minimum etch depth is consistently realised a distance from the end of the channel where etch species cannot additionally access the feature from the side. A length to width ratio of greater than 3:1 is typically desired to ensure maximum ARDE in channels narrower than about 20 μm wide.

FIG. 13 shows a plurality of different example stop designs in plan view. In these examples the one or more protrusions 912 of the rotor are shown attached to the rotor body 904 on the left side. The stator stop feature 914 is shown from above and therefore the walls of the trench of the stop are shown either side of the one or more protrusions 912.

FIG. 13a shows a single protrusion of the rotor and a single stop with a trench feature. The protrusion extends further from the rotor body than the stop.

FIG. 13b shows a single protrusion of the rotor and a single stop with a trench feature. The protrusion ends at the same distance from the rotor body as the stop.

FIG. 13c shows a single protrusion of the rotor and a single stop with a trench feature. The stop feature, and the walls of the trench of the stop, extend further from the rotor body than the protrusion when the rotor is in its equilibrium state. That is, the end of the protrusion does not extend to the end of the trench.

Due to the ARDE and the limits on trench depth at the trench ends, stop designs in FIGS. 13a to 13c are likely to have protrusions which contact the stop at the same point, even though the protrusion is of different lengths.

FIG. 13d shows a stator stop trench with a closed end. The closed end of the stator stop trench or channel may provide an additional transport restriction and hence etch move the minimum etch depth closer to the channel end. That is, the depth of the etch at the closed end of the trench is prevented from exceeding the desired depth as it would with an open end and exposure to the etch species.

FIG. 13e shows an example stator stop and protrusion as shown in FIG. 13d but with added compliance at the base of the rotor protrusion. Such compliance mechanisms are used to build in additional energy to overcome adhesion on contact and reduce the impact shock.

FIG. 13 f shows an example stop comprising an array of n rotor cantilever protrusions (in this example n=2) with channels formed from n+1 stator combs (in this example n+1=3). In this example the protrusions extend beyond the ends of the trenches or channels of the stator comb. However, the length of the protrusions can vary by design as described above.

FIG. 13g shows the same example as in FIG. 13f but the stator stop array in this example has closed ends on the stator comb channels. The closed ends assist in defining the minimum etch depth of the trenches as well as providing a lateral motion stop in combination with the proposed rotational stop.

FIG. 13h shows an example stop with a closed end on the array of protrusions on the rotor. This arrangement allows for additional stiffness in the plane of the rotor on contact, as it represents a box section with a lower mass moment than a cantilever of equivalent width. This is particularly advantageous on a rotor part that tilts in two dimensions. That is, in a design where the rotor comprises a portion which may rotate around two different axes. Thus, in an example, the protrusion may form a box section or series of such sections, where the protrusions are joined to together at a distal end. Such a box configuration of the protrusions may provide additional rigidity when contacting the stop feature, for example if the rotor may possibly be rotated in a second plane.

In any of the above-described examples the base or root of said protrusion(s) may include structures for added compliance. Compliance structure may be implemented to reduce impact stress and store energy to aid overcoming stiction after contact. Such an example is shown in FIG. 13e.

An example of the proposed out-of-plane rotational stop may be configured wherein the one or more protrusions of the rotor are positioned so as to minimise torsional stresses and unbalanced mass moments about the axis of rotation of the rotor. However, it should be understood that the same rotational stop as proposed herein may be implemented with any arrangement of protrusions around the circumference of the rotor, so long as they are configured to contact the base of an appropriately dimensioned trench of the stop so that the protrusion contacts the stop prior to itself or other parts of the rotor contacting other parts of the MEMS device.

The proposed stop is substantially different to existing rotational stops comprising protrusions in that it comprises a high aspect region that defines the distance to the lower stop region using aspect ratio dependent etching. Hence, existing stops solely rely on the additional distance from the axis of rotation of the protrusion tip to make contact before other areas of the rotor.

MEMS devices may be manufactured in a variety of process flows. Typically, they are based on parallel batch fabrication of devices on a substrate using combinations of deposition or growth, photolithography, etching and wafer bonding. The final structure can comprise of a range of materials including, but not limited to, silicon, polysilicon, silicon-germanium, polysilicon-germanium, silicon carbide, titanium, chromium, aluminium, gold, copper, platinum, nickel, silicon oxide, silicon nitride and glass.

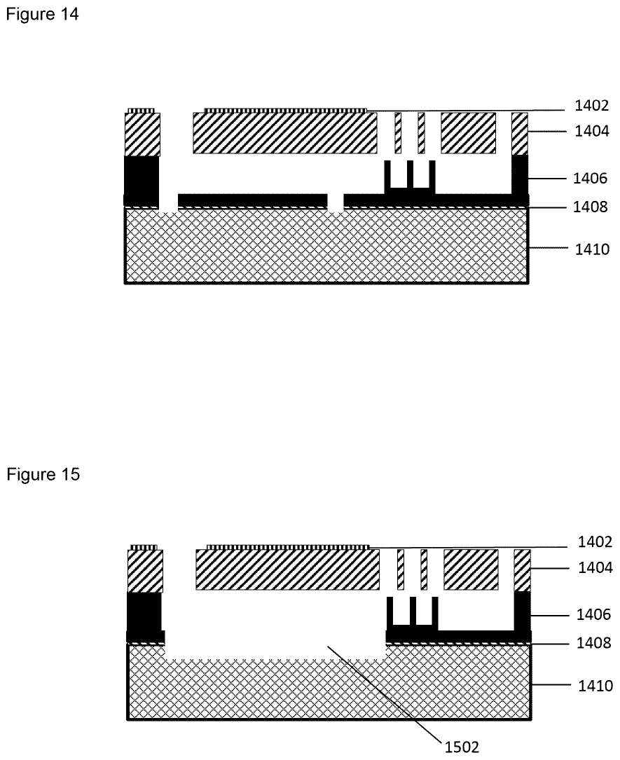

Common process flow families used to manufacture micromirrors include SOI-based micromachining and thick polysilicon-based micromachining with one or more moveable layers. An example method for the manufacture of micromirrors is by way of a double SOI process implementing a single moveable layer and is merely one example presented in order to describe the proposed design more fully. It therefore should not be considered a limitation of the proposed stop that it should be implemented in the described one dimensional and two dimensional tilting mirrors. The MEMS device may be formed from two single layer SOI wafers that are partially patterned using deposition-photolithography-etch cycles prior to bonding and onwards processing. Further deposition-photolithography-etch cycles may then be used on the combined stack to realise the structure. Examples of this structure are shown schematically in FIGS. 14 and 15.

Both of FIGS. 14 and 15 comprise a plurality of layers. As shown in the figures, a top layer comprises one or more metallisations 1402 on a second SOI device layer 1404 (in order of application from the substrate upwards), which are used for external electrical connections, on-chip routing and as a reflector. The second SOI device layer 1404 comprises a rotor (including the upper combs) which is capable of moving—for example, by being suspended by springs (not shown)—and anchored portions which are bonded to a first SOI device layer 1406. The first SOI device layer 1406 comprises a stator, including lower combs which are recessed so they do not bond to the second SOI device layer 1404, and a connecting lower electrode. The first SOI device layer 1406 also comprises full height regions to bond to the second SOI device layer 1404 to enable electrical and mechanical connection to the second SOI device layer 1404. Below the first SOI device layer 1406 is a buried oxide 1408 for electrical isolation and mechanical connection to the supporting SOI handle or substrate 1410. It should be noted that in this cross-sectional schematic, within the lower stator combs the level of the connecting electrode is higher due to ARDE. That is, the base of the trenches between the teeth of the comb is higher than the surrounding etch depth of the same first SOI device layer 1406.

The difference between the flows used to manufacture the device of FIG. 15 versus FIG. 14 is in the area under the rotor (e.g., the mirror) where the recess has been increased to a larger depth between different stator electrode regions. This is achieved by continuing the isolation etching through the buried oxide 1408 and into the SOI handle 1410. Screening of the buried oxide 1408 by the lower electrode 1406 to avoid charging is not required outside electrode areas as the SOI handle 1410 is conductive. These lower layers and metallisation are not shown in other cross-sections herein for clarity, as they are not features pertinent to the implementation of the out-of-plane rotation stops proposed.

Specifically, FIG. 14 shows a double SOI MEMS process final layer stack cross-sectional schematic (not to scale). FIG. 15 shows an alternative implementation of the structure for a double SOI MEMS process final layer stack cross-sectional schematic (not to scale).

Although the above described examples focused on electrostatically-actuated single axis MEMS micromirrors with simple torsion beams, those skilled in the art will appreciate that the electrostatic comb drives may be of an open comb or closed comb (also known as slot) type. Further, other spring designs and arrangements may be used. Therefore, the rotation stops of this disclosure are applicable to many rotating MEMS devices using any transduction method (including, but not limited to, piezoelectric, electrostatic parallel plates, electrothermal and electromagnetic actuation). Similarly, although the above discussion focuses on a device with one rotating portion (rotor) and one static portion (stator), the same arguments apply where contact is between two or more moving portions of the MEMS device.

Although the discussion is focused on electrostatically-actuated MEMS devices using an open or closed comb actuator, those skilled in the art will appreciate this general approach applies to any rotating MEMS device. Similarly, although the discussion focuses on silicon and deep dry etching, the structures required to implement the proposed out-of-plane rotational stops could be realized in other materials or combinations of materials.

The application of the out-of-plane rotor stop designs proposed herein have been described above in the context of a structure with a single axis of rotation for clarity. They are directly applicable to one dimensional tilting micromirrors, but may also be extended to MEMS devices and micromirrors comprising a plurality of moving parts and a plurality of out-of-plane rotation axis. Such mirrors may be gimbaled or non-gimballed. Thus, there is proposed herein a MEMS micromirror using one or both of the out-of-plane rotational stop designs as described above. Where a combination of both types is applied, the design may exploit their relative advantages to realise out-of-plane rotational stops simultaneously in two orthogonal axes.

The above description has provided example implementations of out-of-plane rotational stops of two types (type A and B) and their application to an electrostatically actuated MEMS device comprising a rotor tilting about a single out-of-plane rotational axis. However, as mentioned above, the proposed stops may also be applied to a MEMS device with more than one out-of-plane rotational axis. Such devices may be gimballed or non-gimballed.

FIG. 16 shows an example MEMS device comprising a plurality of axis for out-of-plane rotation and respective rotating portions. This specific example is a gimballed 2D tilting micromirror 1602. The micromirror device comprises two rotating portions, an outer frame 1604 that is suspended and rotated out-of-plane about a first axis A-A, and a central region 1606 incorporating a mirror that is suspended and rotated out-of-plane about a second axis B-B, which is in the same plane but orthogonal to axis A-A. Electrostatic comb drives are included such that when a voltage is applied to the left side comb 1608, the frame 1604 and the central region 1606 rotate about axis A-A in a counter-clockwise direction. Similarly, when a voltage is applied to the right side comb 1610 the same parts rotate about axis A-A in a clockwise direction. That is, when a voltage is applied to the comb on the left side 1608 or the right side 1610 the frame 1604 and the central region 1606 are both rotated into the plane of the page about the axis A-A. Similarly, further electrostatic comb drives are included such that when a voltage is applied to the top comb 1612, the central region 1606 rotates about axis B-B in a direction into the plane of the page, whilst when a voltage applied to the lower comb 1614 the central region 1606 rotates about axis B-B in the opposite direction into the plane of the page. The simple electrostatic drives in this example are provided by way of example but could be any combination of a different array size, different dimensional size, different orientation and in a different location.

In this example, type B rotation stops 1616a and 1616b comprising protrusions and respective stator stops with trenches are applied to the outer frame to limit rotation about axis A-A. Type A rotation stops 1618a-d are applied to the central region to limit rotation about axis B-B. The orientation of stops 1616a and 1616b is ideally selected such that rotation about axis A-A is not restricted by the gap to the high aspect region surrounding the protrusion. The type A stops 1618a-d have a wide gap so they will not contact the central region 1606 under rotation about axis A-A before the type B stops 1616a-b contact the frame 1604, whilst they do have a limiting gap for rotation of the central region 1606 about axis B-B. The distance between the rotor and stator for all of the out-of-plane rotation stops may be larger than that of any lateral motion stops, which are not shown.

The optimal choice of which type of stop to incorporate for which axis depends on may factors, for example the size, arrangement, and rotation angle of each axis as well as the minimum manufacturable gap. The proposed type A post stop 1618a-d is typically better suited to larger angle ranges to have a manufacturable minimum gap. Where larger angle ranges are, for example, greater than about 3 degrees. For example, a tilt limit of 3 degrees at a distance of 500 μm from the axis of rotation for a 50 μm thick rotor would require a 2 μm gap. This can be seen from the example displacement calculations described above in reference to FIG. 6. If the rotor is also rotating around a second axis, as in the example in FIG. 16, then the orthogonal gap in the plane of the rotor (when in its equilibrium state) and parallel to the second axis (e.g., B-B) can be widened so that contact is not made. The proposed type B protrusion and trench stop is well suited to a wide range of angle limits, but in particular may also be moved closer to the axis of rotation for larger angle ranges if needed.

For example, a limit range of about 1-10 degrees would be typical. For example, in reference to FIG. 6, for t=25 um, A-B=1000 um for 35 um change in z at the tip, and the limit is about 2 degrees. However, if moved to A-B=500 um then the limit would be about 4 degrees. Further, if A-B=200 um, the limit would be about 10 degrees. If the stop is moved far in, then there would be a need to ensure the edges of the rotor have sufficient clearance at the target rotation angle so that the stop is contacted first. One way to ensure this is by recessing into the substrate as shown at 1502 in the process cross-section of FIG. 15. Type B stops can be more challenging at low angles—for example, for a limit of about 1 degree, the stop would need to be about 2000 um from the axis of rotation. This may be considered a large distance for a mirror but diameters up to 10 mm have been realised.

Therefore, there is proposed herein a micro-electro-mechanical device comprising at least two rotors arranged to rotate around respective axes. The device comprising at least one of a first stop type and at least one of a second stop type. The first stop type being disposed in a stator structure layer for limiting the rotational motion of a first rotor, the at least one first stop type positioned such that on rotation of the first rotor about its respective axis the initial point of contact is between a surface of the at least one first stop type facing away from the respective axis and a surface of the first rotor facing towards the respective axis. The at least one second stop type being disposed in a stator structure layer for limiting the rotational motion of a second rotor, where the at least one second stop type is positioned such that on rotation of the second rotor about its respective axis the initial point of contact is between a landing site at the base of a trench of the at least one second stop type and a protrusion of the second rotor. It should be understood that in some embodiments the first rotor and second rotor may be the same rotor, the first axis and the second axis may be the same axis, and the first and the second stop type are implemented on the rotor on different sides of same axis.

FIG. 17 shows another example of a gimballed 2D mirror geometry which is suitable for operation in a linear array. A lower frame 1702 is rotated about a first axis A-A that is connected by a cantilever link to an upper mirror 1704. The upper mirror 1704 is rotated about a second axis B-B, which is in the same plane but orthogonal to axis A-A. Electrostatic comb drives are configured such that when a voltage is applied to the comb on the bottom left 1706, the lower frame 1702, link 1703 and upper mirror 1704 regions all rotate about axis A-A in a counter-clockwise direction (that is, into the plane of the page at comb 1706). When a voltage is applied to the comb on the bottom right 1708 the same structures rotate about axis A-A in a clockwise direction (that is, into the plane of the page at comb 1708). Similarly, a further electrostatic comb drive is arranged such that when a voltage is applied to the comb 1710 at the top of the figure, the upper mirror region 1704 rotates about axis B-B. That is, when a voltage is applied to the topmost comb 1710 the upper mirror 1704 rotates about axis B-B such that the topmost edge moves into the plane of the page and the bottom most edges of the upper mirror 1704 moves out from the plane of the page.

In this example, post type rotation stops 1718 are applied to the lower frame to limit rotation about axis A-A whilst protrusion and trench type rotation stops 1716 are applied to the upper mirror region to limit rotation about B-B. The post type stops 1718 are within the repeating unit of the lower frame and so do not limit the pitch. If protrusion and trench type stops 1716 were used on the lower frame they could affect the pitch of the linear array, reducing the array density. Preferably the distance between the rotor and stator in all the out-of-plane rotation stop designs proposed herein is larger than that of any lateral motion stops (not shown) when the rotor is in its equilibrium state.

The upper mirror 1704 is capable of rotating about both axes A-A and B-B. This means the corners at the furthest extents in x will translate further in the z direction (i.e., into and out of the plane of the page), than any location on the y-axis, i.e., on line A-A. For an out-of-plane rotation stop dependent only on the tilt about B-B, then the protrusion and trench type stop 1716 should be located on the axis A-A. A further advantage of this would be to minimise the protrusion sidewall translation towards the high aspect region in the stator layer, and thus rotation in axis A-A would only cause rotation of the protrusion and not translation in the x direction.

In practice, it is the corners of the upper body furthest away from the A-A axis that translate most in z and hence will contact first unless a significantly longer protrusion is used on the A-A axis location in comparison to as would be needed on the corners as shown in FIG. 17, with the drawbacks already described earlier. Thus, the corners are also where the protrusion and trench type stops 1716 would ideally be located, as in FIG. 17, so they contact first in rotation about B-B when the device is also rotated about axis A-A. The sidewall of the protrusion and trench type stop 1716 will also rotate with tilt about A-A and also reduce the gap towards the high aspect trench sidewall. The gap reduction will increase with distance from the A-A axis of rotation. This may limit the application of the protrusion and trench type stop in cases where the corners are a long way from the A-A axis of rotation or at high tilt angles of the outer frame. This is because the high aspect region defines the angle limit and ensures first contact is at the stop and so cannot be easily widened to avoid full closure of the gap upon tilting. In an embodiment it may be possible to create a recess under outer portions of the mirror to avoid corners of the rotor contacting before the centre. For example, using the process flow of FIG. 15.

If a post type stop were used for stopping rotation about axis B-B then a single stop centred on the axis A-A, or stops at the two corners at the upper end of the device could be used provided the gap was sized so that it was contacted before the corners of the upper body when rotated in both axes.

The use of substantially vertical faces in the proposed post type stop design for limiting rotation between a rotor and a stator, where the rotor contact area faces towards the axis of rotation and the stator contact area away from the axis of rotation, means that the angle limit is defined by the geometry. Specifically, the rotor-stator gap and the distance from the axis of rotation. This makes the out-of-plane stop design proposed particularly suitable for large angles close to the axis of rotation. This is because the dimensions of the contacting surfaces or points are not significantly changed upon rotation of the rotor, unlike for other stop designs.

The proposed post type stop (type A) gives flexibility in its location on a device as, for example, it is not limited to being implemented at the edge of a rotor of a device. Similarly, the stop does not extend the footprint of the device. This allows for an ability to realise dense arrays of devices, with complicated designs (e.g., inclusion of multiple drive combs in specific locations), while also being able to implement the stop as needed in limited space.

In an example implementation the vertical faces of the proposed post type stop (type A) do not overlap. By not using overlapping vertical faces in-plane motion causing unwanted contact is avoided and thus simple integration with conventional in-plane stops is facilitated.

The proposed protrusion and trench type stop (type B) contacts at a different level above or below it, where the local height difference is defined (at least in part) by aspect ratio dependent etching (ARDE). The stop protrusion will typically be on the rotor body at the largest distance from the axis of rotation (e.g., a short protrusion from the main rotor body of the rotor). The angle limit is defined by a combination of the distance of the rotor stop from the axis of rotation and the height difference (when in its equilibrium state) to the stator stop. In this case the stator stop height is at least in part defined by ARDE such that the etch depth is locally more limited (by high aspect ratio) and will therefore be contacted before other parts of the device. That is, where at least in part means that at least the depth of the contacted part of the trench is defined by ARDE. The short protrusion means that any increase in mass moment and associated reduction in rotational frequency is limited. It also means that the increase in the footprint of the device is minimised.

The proposed stops (type A and B) may be realized without additional process complexity. That is, no additional process steps are required, meaning no additional process cost and no risk of reduced yield from the additional steps are incurred.

Compliance mechanisms can be added to the proposed stops (type A and B), which allow additional energy to be stored on contact. This reduces peak contact stress and provides additional energy to overcome stiction after contact.

The proposed stops (type A and B) should ensure contact is made between the rotor and the stator at regions of the same electrical potential. This avoids short circuit or breakdown between different potentials on or near contact. It also avoids unwanted actuation variability that could arise if one or more contacting structures were floating.

The rotation stops proposed herein (type A and B) may be combined on the same device. Similarly, the two proposed designs may be implemented alongside existing conventional stop types. Additionally, either of the proposed stops or a combination of both of the stops (types A and/or B), may be used to realise out-of-plane rotational stops in more than one axis of rotation in a single device. This enables the optimal stop to be selected for the purpose in a given design. The proposed post type stop (type A) may be formed within the device boundaries, so avoiding the need for a larger pitch in array devices. When close to the axis of rotation, the target gap within the stop between layers may become too small to be manufacturable if the angle is not sufficient. For example, in FIG. 6, with a distance of 250 um (A-B), a rotor thickness t=25 um, and for about a 1 degree stop angle, the gap required would be approximately 0.255 um. If the alignment and CD tolerances are, for example, +/−0.25 um, then this is of the same order as the size of the gap and not manufacturable. It should be noted that potential issues should be avoidable by selecting an appropriate stop dimension. The proposed stop allows for more control over the stop angle at smaller angles compared to existing designs.

The proposed protrusion and trench type rotation stop (type B) is typically best suited for use when at or close to the maximum distance from the axis of rotation. A device comprising two axes (e.g., orthogonal axis) for out-of-plane rotation may be supported using out-of-plane rotational stops for each axis of both type A and B, or type A, or type B. Where type A is the proposed post type rotational stop and type B is the proposed protrusion and trench type rotational stop.

The proposed stops are broadly applicable to any MEMS device with an out-of-plane rotational motion. Applications include, but are not limited to, micromirrors for Wavelength Selective Switching (WSS) and the all optical network, scanning micromirrors for pico-projection (including head up displays), automotive and industrial Light Detection and Ranging (LIDAR) and Augmented Reality (AR) headsets, and inertial sensors for consumer and automotive applications.

The proposed stops are applicable to any MEMS device with an out-of-plane rotational axis. Examples include z-axis accelerometers, which may be part of a MEMS inertial measurement unit (IMU) and micromirrors for reflecting light in a specified direction. Micromirrors may be used in optical telecommunications applications to change the path of light, for example in a variable optical attenuator, an optical cross-connect switch, a wavelength selective switch, and an optical power modulator. They may also be used in laser beam scanning applications, such as bar code readers, LIDAR, pico-projection, augmented reality glasses, and head-up displays (HUD).

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present disclosure may consist of any such individual feature or combination of features. In view of the foregoing description it will be evident to a person skilled in the art that various modifications may be made within the scope of the disclosure.

1. A micro-electro-mechanical device, the micro-electro-mechanical device comprising:
a rotor having an axis of rotation along a length of the rotor; and
a stop for limiting out-of-plane rotational motion of the rotor, the stop positioned such that on rotation of the rotor about the axis of rotation a first point of contact is between a surface of the stop facing away from the axis of rotation and a surface of the rotor facing towards the axis of rotation.

2. The micro-electro-mechanical device according to claim 1, wherein the surface of the stop facing away from the axis of rotation extends outwardly from a plane of a substrate of the micro-electro-mechanical device.

3. The micro-electro-mechanical device according to claim 1, wherein the stop is formed in one or more layers of the micro-electro-mechanical device that form a stator structure of the micro-electro-mechanical device.

4. The micro-electro-mechanical device according to claim 1, wherein the rotor contacts the stop at a region of the stop with same potential as the rotor.

5. The micro-electro-mechanical device according to claim 1, wherein the rotor defines a throughway in which at least part of the stop is located.

6. The micro-electro-mechanical device according to claim 1, wherein the micro-electro-mechanical device comprises at least one spring biasing the rotor to an equilibrium state.

7. The micro-electro-mechanical device according to claim 6, wherein the stop is located such that when the rotor is in the equilibrium state the stop is spaced from the rotor in a direction normal to a substrate of the micro-electro-mechanical device.

8. The micro-electro-mechanical device according to claim 6, wherein the stop is located such that when the rotor is in the equilibrium state the stop overlaps the rotor in a direction normal to a substrate of the micro-electro-mechanical device.

9. The micro-electro-mechanical device according to claim 6, wherein the stop is located such that when the rotor is in the equilibrium state the stop extends further from a substrate of the micro-electro-mechanical device than the rotor.

10. The micro-electro-mechanical device according to claim 1, wherein the micro-electro-mechanical device comprises a plurality of stops, wherein the plurality of stops is positioned symmetrically about a line along the axis of rotation of the rotor and each stop of the plurality of stops has the same dimensions.

11. The micro-electro-mechanical device according to claim 1, wherein the micro-electro-mechanical device comprises a plurality of stops, wherein the plurality of stops is positioned asymmetrically about a line along the axis of rotation of the rotor and at least one stop of the plurality of stops has different dimensions that another stop of the plurality of stops.

12. The micro-electro-mechanical device according to claim 1, wherein the micro-electro-mechanical device comprises a plurality of stops, wherein the plurality of stops is positioned asymmetrically about a line along the axis of rotation of the rotor and each stop of the plurality of stops has the same dimensions.

13. The micro-electro-mechanical device according to claim 1, wherein a portion of the rotor comprising the surface of the rotor facing towards the axis of rotation is attached to a remainder of the rotor by a compliant mechanism for reducing impact on the rotor upon contact with the surface of the stop facing away from the axis of rotation.

14. A method of manufacturing a micro-electro-mechanical device, the method comprising:
disposing a first layer for forming a stator structure on a base layer; and
etching into the first layer to form the stator structure and at least one stop, wherein the stop comprises a trench formed by aspect ratio-dependent etching with walls bounding a landing site at a base of the trench, the stop is formed a distance away from an axis of rotation of a rotor such that on rotation of the rotor about its axis the base of the trench is contacted by the rotor before contacting any other features of the micro-electro-mechanical device.

15. The method of manufacturing the micro-electro-mechanical device according to claim 14, further comprising:
disposing a second layer for forming the rotor; and
etching into the second layer to form the rotor having the axis of rotation and comprising a protrusion dimensioned to make contact with the base of the trench.

16. The method of manufacturing the micro-electro-mechanical device according to claim 14, wherein the etching into the first layer comprises etching the trench with a length at least three times its width.

17. The method of manufacturing the micro-electro-mechanical device according to claim 14, wherein the etching into the first layer is by deep silicon etching.

18. The method of manufacturing the micro-electro-mechanical device according to claim 15, wherein the etching the second layer comprises forming the protrusion as one or more cantilevers of the rotor.

19. The method of manufacturing the micro-electro-mechanical device according to claim 15, wherein the etching the second layer comprises forming the protrusion as a plurality of cantilevers, wherein at least one cantilever of the plurality of cantilevers is joined at a distal end to at least one other cantilever of the plurality of cantilevers to form an enclosed void therebetween.

20. A micro-electro-mechanical device comprising at least two rotor portions arranged to rotate around respective axes, the micro-electro-mechanical device comprising:
at least one of a first stop type disposed in a stator structure layer for limiting out-of-plane rotational motion of a first rotor portion, wherein the at least one first stop type is positioned such that on rotation of the first rotor portion about its respective first axis an initial point of contact of the first rotor portion is between a surface of the at least one first stop type facing away from the respective first axis and a surface of the first rotor portion facing towards the respective first axis; and
at least one of a second stop type disposed in a stator structure layer for limiting rotational motion of a second rotor portion, wherein the at least one second stop type is positioned such that on rotation of the second rotor portion about its respective second axis an initial point of contact of the second rotor portion is between a landing site at a base of a trench of the at least one second stop type formed by aspect ratio-dependent etching and a protrusion of the second rotor portion.
